(19) United States
(12) Patent Application Publication
(10) Pub. No.: US 2024/0394425 A1
(43) Pub. Date: Nov. 28, 2024

(54) DESIGN SYSTEM, INFORMATION PROCESSING DEVICE, STORAGE MEDIUM, OUTPUT DEVICE, AND METHOD

(71) Applicant: NEC Corporation, Minato-ku, Tokyo (JP)

(72) Inventors: Kazuki Tanabe, Tokyo (JP); Takayuki Kuroda, Tokyo (JP)

(73) Assignee: NEC Corporation, Minato-ku, Tokyo (JP)

(21) Appl. No.: 18/704,539

(22) PCT Filed: Nov. 12, 2021
(86) PCT No.: PCT/JP2021/041753

§ 371 Date: Apr. 25, 2024

(51) Int. Cl. G06F 30/13

(52) U.S. Cl. CPC G06F 30/13

(57) ABSTRACT

An information processing device provided with a similar information acquisition unit that, when definition information for a design target has been input, acquires similar requirement information, which is requirement information associated with definition information similar to definition information of the design target, based on association information in which a set of definition information including one or multiple requirement elements, requirement information indicating the requirements represented by a component group, and configuration information indicating a configuration represented by a component group have been associated in advance, and a configuration design unit that generates new configuration information with respect to requirement information based on the definition information of the design target, by applying conversion rules that were applied to a portion of a component group represented by the similar requirement information, and thereafter performing the configuration generation process.

### TECHNICAL FIELD

The present disclosure relates to a design system, an information processing device, a storage medium, an output device, and a method.

### BACKGROUND ART

In various business fields, design-based services and products are provided by designing specific configurations from requirements, etc.

As technology for automating such design, for example, in the field of ICT (information communication technology) systems, Patent Document 1 describes concretization using concretization rules in which abstract configuration information including system configuration requirements are stored, thereby generating, based on the configuration requirements, system configuration information, which is information indicating system configurations not including the undecided portions. Patent Document 2 describes displaying system requirement similarities of projects, number of manual tasks, and environment construction instructions used in a project. Patent Document 3 describes a person in charge of development pre-registering, as basic requirements and basic functions, requirements and functions that are fundamental when developing a system, and registering more detailed and specific content therein so as to be divided among multiple types of objects provided with different content and levels (granularity), such as sub-requirements, system requirements, and software specifications.

Non-Patent Document 1 describes technology necessary for evaluating the performance of products comprising an ICT system, wherein a comprehensive evaluation environment is automatically generated. Non-Patent Document 2 describes a method for autonomously acquiring knowledge necessary for design by making use of AI (artificial intelligence) and machine learning. Non-Patent Document 3 describes generating specific service configurations based on abstract customer demands and the environment in which services are to be deployed.

### CITATION LIST

### Patent Literature

[Patent Document 1] PCT International Publication No. WO 2019/216082
[Patent Document 2] Japanese Unexamined Patent Application, First Publication No. 2013-114437
[Patent Document 3] Japanese Unexamined Patent Application, First Publication No. 2005-352869

### Non-Patent Documents

[Non-Patent Document 1] Kazuki TANABE et al., “An Automation Technology of Testing Environment Configuration for ICT System Products by Search-based System Design Generation Scheme”, IEICE Technical Report, The Institute of Electronics, Information and Communication Engineers, March 2021, Vol. 120, No. 433, ICM2020-60, pp. 7-12.
[Non-Patent Document 2] Takayuki KURODA et al., “Acquisition of Knowledge about ICT System Designing with Machine Learning”, IEICE Transactions, The Institute of Electronics, Information and Communication Engineers, Mar. 1, 2021, Vol. J104-B, No. 3, pp. 140-151.
[Non-Patent Document 3] Takayuki KURODA et al., “A Novel Configuration Designer for IT/NW Services in Heterogeneous Environments”, 2019 IEEE Global Communications Conference (GLOBECOM), December 2019

### SUMMARY OF THE INVENTION

### Problems to be Solved by the Invention

Regarding the automation (including semi-automation) of design, there are cases in which time is required for processing, and increased processing speed is desired.

One purpose of the present disclosure is to provide a design system, an information processing device, a storage medium, an output device, and a method that can solve the above-mentioned problem.

### Means for Solving the Problems

(1) The present disclosure pertains to a design system for performing a configuration generation process for generating, with respect to a design target for which requirements are indicated, configuration information for the design target by repeatedly applying conversion rules to configuration components of the design target, the design system being provided with: a storage unit that stores association information in which a set of definition information comprising one or multiple requirement elements, requirement information indicating the requirements represented by a component group, and configuration information indicating a configuration represented by a component group have been associated in advance; a determination unit that determines, based on the association information, in a case in which definition information for the design target has been input, whether to perform a first process for outputting configuration information in the association information or to perform a second process for outputting configuration information generated by the configuration generation process; a similar information acquisition unit that selects, based on the association information, in a case in which the second process is to be performed, similar definition information, which is definition information similar to definition information of the design target, and that acquires similar configuration information, which is configuration information associated with the similar definition information; a configuration design unit that generates new configuration information by applying conversion rules that were applied to a portion of a component group represented by the similar requirement information to requirement information based on the definition information of the design target, and thereafter performing the configuration generation process; and an information management unit that stores, in the storage unit, as the association information, a set including the definition information of the design target and the new configuration information.

(2) The present disclosure pertains to an information processing device that is a configuration design device for performing a configuration generation process for generating, with respect to a design target for which requirements are indicated, configuration information for the design target by repeatedly applying conversion rules to configuration components of the design target, the information processing device being provided with: a similar information acquisition unit that, when definition information for the design target has been input, acquires similar requirement information, which is requirement information associated with definition information similar to definition information of the design target, based on association information in which a set of definition information comprising one or multiple requirement elements, requirement information indicating the requirements represented by a component group, and configuration information indicating a configuration represented by a component group have been associated in advance; and a configuration design unit that generates new configuration information by applying conversion rules that were applied to a portion of a component group represented by the similar requirement information to requirement information based on the definition information of the design target, and thereafter performing the configuration generation process.

(3) The present disclosure pertains to a storage medium having, stored therein, a trained model to be used in a configuration design device for performing a configuration generation process for generating, with respect to a design target for which requirements are indicated, configuration information for the design target by repeatedly applying conversion rules to configuration components of the design target, wherein: the trained model is generated by performing machine learning based on sets of requirement information indicating the requirements represented by component groups and configuration information indicating configurations represented by the component groups; and new configuration information is added to the trained model by applying, to requirement information based on definition information of the design target, conversion rules that were applied to a portion of a component group represented by similar requirement information associated with definition information similar to the definition information of the design target in association information in which a set of definition information comprising one or multiple requirement elements, the requirement information, and the configuration information have been associated in advance, and thereafter performing the configuration generation process.

(4) The present disclosure pertains to an output device for displaying, with respect to a design target for which requirements are indicated, configuration information of the design target generated by repeatedly applying conversion rules to configuration components of the design target, wherein the output device is provided with an output control unit that displays an input form for receiving inputs of requirement elements from a user, and with respect to definition information comprising requirement elements input to the input form, a graph structure including images of the graph elements regarding configuration information associated with the definition information by referencing association information in which a set of definition information comprising one or multiple requirement elements, requirement information indicating the requirements represented by a first group of graph elements representing nodes or edges, and configuration information indicating configurations represented by a second group of the graph elements have been associated in advance.

(5) The present disclosure pertains to a method in a design system for performing a configuration generation process for generating, with respect to a design target for which requirements are indicated, configuration information for the design target by repeatedly applying conversion rules to configuration components of the design target, wherein the method involves: storing association information in which a set of definition information comprising one or multiple requirement elements, requirement information indicating the requirements represented by a component group, and configuration information indicating a configuration represented by a component group have been associated in advance; determining, based on the association information, in a case in which definition information for the design target has been input, whether to perform a first process for outputting configuration information in the association information or to perform a second process for outputting configuration information generated by the configuration generation process; selecting, based on the association information, in a case in which the second process is to be performed, similar definition information, which is definition information similar to definition information of the design target, and acquiring similar requirement information, which is requirement information associated with the similar definition information; generating new configuration information by applying conversion rules that were applied to a portion of a component group represented by the similar requirement information to requirement information based on the definition information of the design target, and thereafter performing the configuration generation process; and storing, in a storage unit, as the association information, a set including the definition information of the design target and the new configuration information.

### Advantageous Effects of Invention

According to the present disclosure, the processing speed for design can be increased.

### BRIEF DESCRIPTION OF THE DRAWINGS

FIG. 1 is a diagram illustrating the outer appearance of a design device according to a first embodiment.

FIG. 2 is a diagram representing an example of a screen display according to the present embodiment.

FIG. 3 is an explanatory diagram for explaining an example of a method for deriving a configuration from requirements according to the present embodiment.

FIG. 4 is a diagram illustrating an example of system requirements according to the present embodiment.

FIG. 5 is a diagram illustrating an example of system requirements before applying a conversion rule according to the present embodiment.

FIG. 6 is a diagram illustrating an example of system requirements after applying a conversion rule according to the present embodiment.

FIG. 7 is an explanatory diagram for schematically explaining a design device according to the present embodiment.

FIG. 8 is a schematic block diagram illustrating the configuration of the design device according to the present embodiment.

FIG. 9 is a diagram indicating an example of a similar design selection process according to the present embodiment.

FIG. 10 is a diagram indicating a requirement generation process according to the present embodiment.

FIG. 11 is a diagram indicating an example of a configuration design process according to the present embodiment.

FIG. 12 is a flow chart indicating a process in a design device according to the present embodiment.

FIG. 13 is a flow chart indicating a design process according to the present embodiment.

FIG. 14 is a schematic block diagram illustrating the configuration of a configuration design unit according to the present embodiment.

FIG. 15 is a diagram indicating an example of history information according to the present embodiment.

FIG. 16 is a diagram indicating an example of association relationships in integrated data according to the present embodiment.

FIG. 17 is a flow chart indicating an example of a configuration generation process according to the present embodiment.

FIG. 18 is a flow chart indicating an example of a concretization design process according to the present embodiment.

FIG. 19 is a flow chart indicating an example of a node evaluation process according to the present embodiment.

FIG. 20 is a flow chart indicating an example of a training data generation process according to the present embodiment.

FIG. 21 is a flow chart indicating an example of a requirement evaluation process according to the present embodiment.

FIG. 22 is an explanatory diagram indicating a comparative example of a process history according to the present embodiment.

FIG. 23 is an explanatory diagram indicating another comparative example of a process history according to the present embodiment.

FIG. 24 is a diagram indicating another example of history information according to the present embodiment.

FIG. 25 is a schematic block diagram illustrating the configuration of a design system according to a second embodiment.

FIG. 26 is a schematic block diagram illustrating the configuration of a design device according to a modified example of the embodiment.

FIG. 27 is a schematic block diagram illustrating the configuration of a display device according to a modified example of the embodiment.

FIG. 28 is a flow chart indicating the process in a design system according to a modified example of the embodiment.

FIG. 29 is a schematic block diagram illustrating the configuration of a computer according to at least one embodiment.

### EXAMPLE EMBODIMENT

Hereinafter, embodiments of the present invention will be explained. However, the embodiments below are not to be construed as limiting the invention as claimed. Additionally, not all combinations of the characteristics described in the embodiments are necessarily essential to the solutions provided by the invention.

### First Embodiment

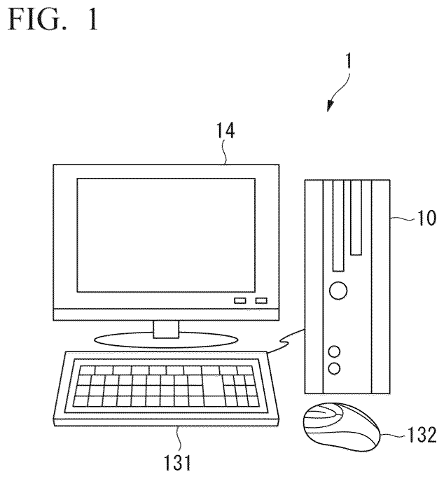

FIG. 1 is a diagram illustrating the outer appearance of a design device 1 according to a first embodiment.

The design device 1 is, for example, a personal computer (PC) and is configured to include a main body 10, an input device 13 such as a keyboard 131 or a mouse 132, and a display 14.

The display device 1 automatically (including semi-automatically) implements design. Specifically, the design device 1 generates requirements in response to definitions input from the input device 13. The design device 1 is a design system that designs configurations from the generated requirements and that displays the configuration on a display 14. In this case, definitions are sets of elements (also referred to as “requirement elements”) that make us the requirements. Additionally, the requirements and configurations are described by graph structures. The requirements are described in a more abstract manner than the configurations, and components (the nodes and edges to be described below) in the graph structures of the requirements are converted to components in the graph structures of the configurations.

In the present embodiment, the design device 1 designs ICT (Information and Communication Technology) systems. Hereinafter, in the case of an ICT system, the design, the definitions, the requirements, and the configuration will also be referred to, respectively, as the “system design”, the “system definitions”, the “system requirements” and the “system configuration”.

However, what is to be designed by the design device 1 is not limited to a specific field. For example, the design device 1 can be applied to the designing of configurations for services, products, etc. from definitions thereof. In that case, the terminology such as system design, system definitions, system requirements, and system configuration in the embodiment may be replaced with terminology such as service design, service definitions, service requirements, and service configuration, or with product design, product definitions, product requirements, and product configuration.

The design device 1 is an example of a design system. Some of the functions of the design device 1 may be provided in one or multiple devices, and the design system may be provided with multiple devices. For example, the design device may be configured by using a computer such as a workstation, or may be configured by using hardware dedicated to the design device 1, such as being configured by using an SIC (Application-Specific Integrated Circuit). Additionally, the design system may be configured by distributing the functions among multiple devices, such as a cloud computing system.

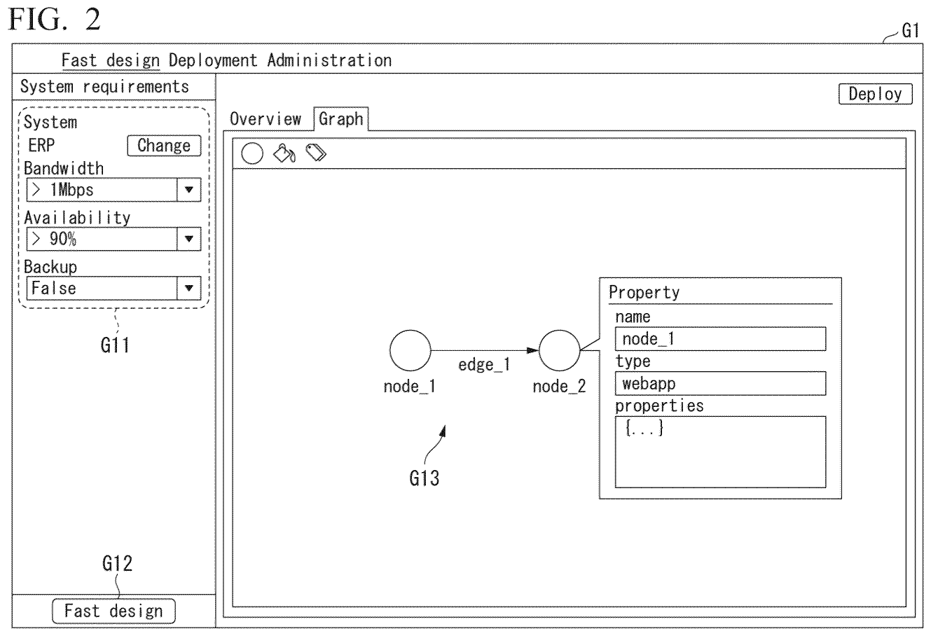

FIG. 2 is a diagram indicating an example of a screen display according to the present embodiment. This screen display G1 is a user interface (Graphical User Interface; GUI) that is displayed to a user by the design device 1. The user is, for example, a designer performing system design.

In the screen display G1, system definitions are input to an input form G11 by the user. In this input form G11, values are input, as system definitions, for some or all of the requirement elements, such as system type, bandwidth, availability, and whether or not a backup is required. In this case, the system type represents the type of system, and is, for example, facial authentication, ERP (core information system), web, etc. The bandwidth indicates the communication bandwidth, and as units, for example, bps (bits per second) are used. The availability represents an indicator of how much the system continues to operate without stopping, and is represented by an operating rate. Requirement elements may be added to or deleted from the system definitions in the input form G11. For example, the throughput, the presence/absence of a firewall, the presence/absence of a DMZ (DeMilitarized Zone), the presence/absence of authentication functions, the presence/absence of mail functions, etc. may be pre-stored, and requirement elements for the system definitions may be added by a user selecting requirement elements.

For example, after the respective items in the input form G11 have been input in accordance with selection operations by a user from among options displayed in the form of a pull-down menu, when the button G12 is pressed, a system configuration G13 (referred to as “system configuration G13”) is displayed in accordance with the respective items that have been input.

The system configuration G13 is represented by a graph structure based on graph theory. The nodes and edges are each elements (also referred to as “graph elements”) describing a graph structure. In the present disclosure, the graph elements are also referred to as “components”. The graph structure is represented by a “component group”, which is a set of components. The nodes are points such as nodal points and vertices, and are represented by circles in the system configuration G13. The edges are lines such as branches and sides, and are represented by directed arrows in a system configuration G13 with a directed graph. The graph structure of the system configuration G13 may be an undirected graph.

Property information is appended to each of the nodes and edges. In the system configuration G13, a certain node (node_1) is selected by the user, and a property window (Property) of that node is displayed. The property window includes a property name, a type, and property information.

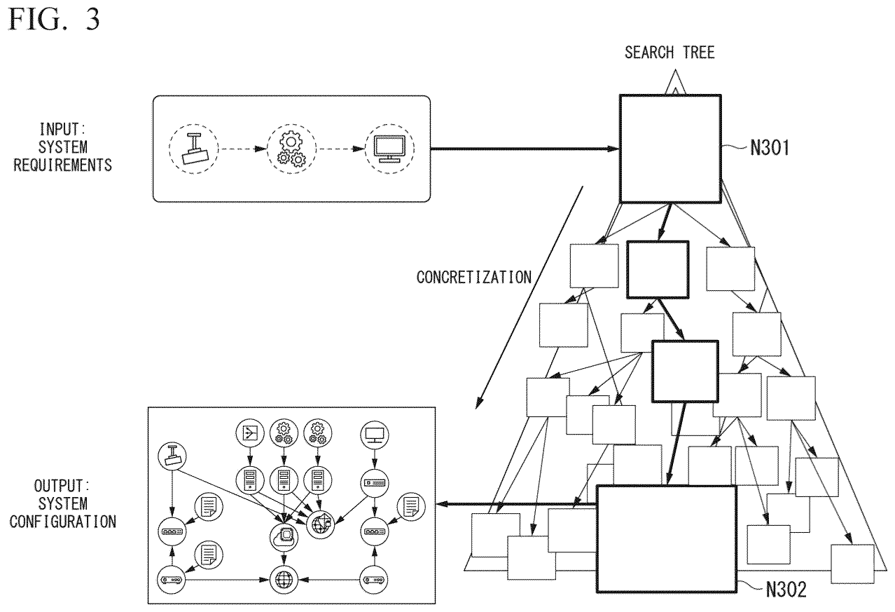

FIG. 3 is an explanatory diagram for explaining an example of a method for deriving a configuration from requirements according to the present embodiment.

As an example of the method, an example in which a search tree is used will be explained. The search tree illustrated in FIG. 3 is a trained model that has been generated or updated by machine learning in the design device 1, and is pre-stored in the design device 1 as integrated data. The design device 1 generates system requirements from system definitions, takes the generated system requirements as inputs, and converts them to an associated system configuration in the search tree. The design device 1 outputs the converted system configuration (see FIG. 2).

In the search tree, the nodes represent system requirements and the edges represent conversion rules. The edges are set from nodes at which the conversion rules have not been applied towards nodes at which the conversion rules have been applied. Multiple edges having a single node as a starting point represent multiple conversion rules that are applicable to the same system requirement.

In the search tree illustrated in FIG. 3, the node N301 is a root. The node N302 is one leaf. For example, one path from the root to a leaf, like the path from the node N301 to the node N302, represents the procedure for a single system design.

Applying a conversion rule to a system requirement is referred to as conversion. Additionally, when it is explicitly indicated that multiple conversion rules can be applied to a system requirement, this is referred to as a conversion series. Therefore, a conversion series is indicated by one or more serially connected conversions.

The node from which the system design starts is not limited to being a root. For example, in the case in which a concretized system requirement is input to the design device 1, a node other than a root may be the node from which the system design starts. A concretized system requirement is, for example, a system requirement matching a node other than the root of the search tree.

Additionally, the node at which the system design ends is not limited to being a leaf. For example, in the case in which a rule to replace a concretized component with another concretized component is included as one of the conversion rules, the system design can be considered to be completed as a result of concretizing the system requirements to a deployable level at a node other than a leaf.

The leaf nodes indicate system configurations. However, a node other than a leaf at which the system design ended (for example, a node other than a leaf at which the system requirements have been concretized to a deployable level) may also be considered to indicate a system configuration.

Additionally, integrated data may be represented by various effective graphs without being limited to trees, in accordance with the conversion rules used for system design. For example, if a first system requirement leads to the same second system requirement whether any of different conversion series are applied, then the integrated data includes multiple paths from the first node to the second node. In this case, the integrated data may be represented by a lattice.

Additionally, the integrated data may include two or more subgraphs that are independent of each other. The two subgraphs being independent of each other in this case means that, between the two subgraphs, there is no path leading from the first subgraph to the second subgraph, and there is no path leading from the second subgraph to the first subgraph. For example, the integrated data may be represented by a forest.

Additionally, the integrated data may be any of a trained model other than one having a search tree or a tree structure, a table, a function, or a combination thereof, and multiple conversion procedures may be included.

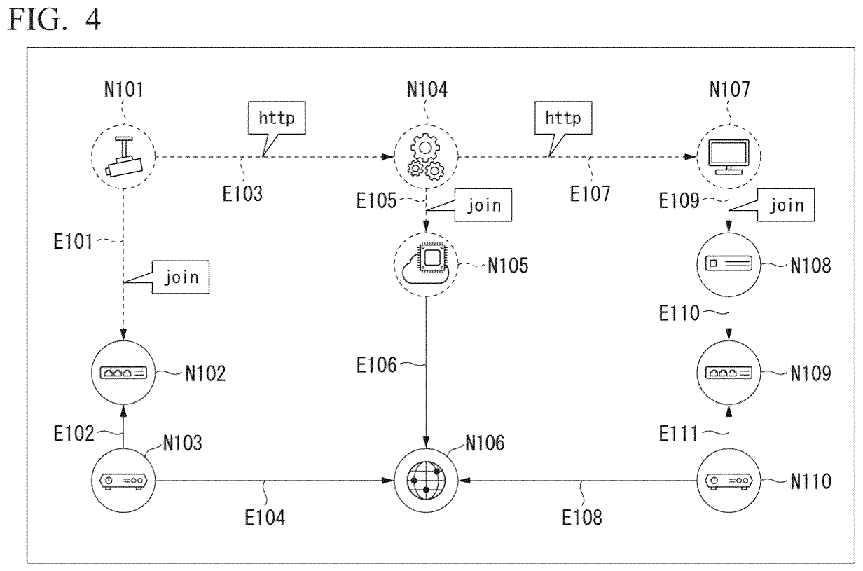

FIG. 4 is a diagram illustrating an example of the system requirements according to the present embodiment. These system requirements are an example of a node in the search tree in FIG. 3, and represent the system requirements for a suspicious person detection system for detecting a suspicious person.

The system requirements in FIG. 4 are represented by a graph structure for a directed graph, having property information appended to each of the nodes and edges. The system requirements, like the system configuration G13, are represented by a “component group”, which is a set of components (graph elements). The system requirements may also be an undirected graph.

For example, the name or identification information for a function, a device, etc. indicated by a node may be appended, as property information, to that node. In the case of the example in FIG. 4, the node N101 represents a camera function (image capture function). The nodes N102 and N109 each indicate network switches. The nodes N103 and N110 both indicate routers. The node N104 represents a facial authentication function. The node N105 represents a cloud infrastructure. The node N106 represents a WAN (Wide Area Network). The node N107 represents a monitor function (image display function). The node N108 represents a server device.

Additionally, a degree of abstraction of a node may be appended, as property information, to that node. In the case of the example in FIG. 4, the nodes N101, N104, N105, and N107 are abstract nodes. Meanwhile, the nodes N102, N103, N106, N108, N109, and N110 are concrete nodes. In this case, an abstract node is a node that can be converted to a node representing a more concrete configuration than the current configuration by referencing a predefined conversion rule at least once. Meanwhile, a concrete node (i.e., a node concretized to a deployable level) is a node that cannot be converted to a node representing a more concrete configuration, even by referencing the conversion rule.

The design device 1 applies said conversion rule to the system requirements so as to concretize the abstract node. For example, the design device 1 may apply, to the system requirements illustrated in FIG. 4, a conversion rule to convert the node N101 representing a camera function to a subgraph including a node for a camera (image capture device) and a node for a control device for controlling the camera.

Additionally, in the example in FIG. 4, the property information “join” is indicated for each of the edges E101, E105, and E109, and the property information “http” is indicated for each of the edges E103 and E107. The property “join” represents a membership relationship. For example, the camera function represented by the node N101 is included in the LAN (Local Area Network) formed by the network switch represented by the node N102. The facial authentication function represented by the node N104 is provided on the cloud infrastructure represented by the node N105. The monitor function represented by the node N107 is controlled by using the server device represented by the node N108.

The property “http” represents communication using HTTP (HyperText Transfer Protocol). For example, the edge E103 indicates that data is transmitted, by HTTP, from the camera function represented by the node N101 to the facial authentication function represented by the node N105. The edge E107 indicates that data is transmitted, by HTTP, from the facial authentication function represented by the node N105 to the monitor function represented by the node N107.

Additionally, the degree of abstraction of an edge may also be appended, as property information, to that edge. In the case of the example in FIG. 4, the edges E101, E103, E105, E107, and E109 are abstract edges. Meanwhile, the edges E102, E104, E106, E108, E110, and E111 are concrete edges. In this case, an abstract edge is an edge that can be converted to an edge representing a more concrete configuration than the current configuration by referencing a predefined conversion rule at least once. Meanwhile, a concrete edge is an edge that cannot be converted to an edge representing a more concrete configuration (i.e., an edge concretized to a deployable level), even by referencing the conversion rule.

The conversion rules used by the design device 1 may include conversion rules for concretizing edges.

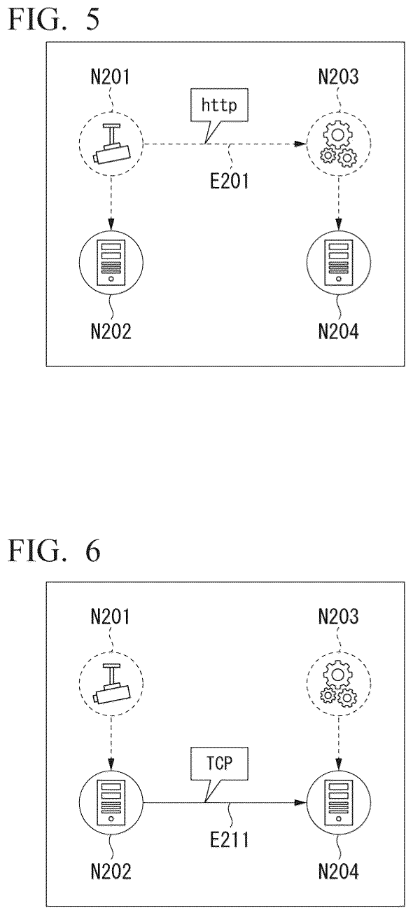

FIG. 5 is a diagram illustrating an example of system requirements before applying a conversion rule according to the present embodiment. In the system requirements illustrated in FIG. 5, the camera function represented by the node N201 is connected to the workstation represented by the node N202. Additionally, the facial authentication function represented by the node N203 is executed on the workstation represented by the node N204. The edge E201 indicates that data is transmitted, by HTTP, from the camera function represented by the node N201 to the facial authentication function represented by the node N203.

FIG. 6 is a diagram illustrating an example of the system requirements after applying a conversion rule according to the present embodiment. FIG. 6 illustrates an example in which the conversion rule has been applied to the system requirements indicated in FIG. 5.

In FIG. 6, the edge E211 is provided instead of the edge E201 in FIG. 5. The edge E211 indicates that data is transmitted, by using TCP (Transmission Control Protocol), from the workstation represented by the node N202 to the workstation represented by the node N204. Thus, FIG. 6 shows that, by applying the conversion rule to the system requirements in FIG. 5, a conversion was made to concretize the communication using HTTP to communication using TCP.

However, the systems to which the design device 1 to be targeted may be various types of systems that include components. The methods for expressing systems to which the design device 1 is applied may be various expression methods by which conversion rules can be applied by specifying component types.

Among multiple predefined conversion rules, situations occur in which the content (configuration) representing system requirements after conversion differs depending on what conversion rules are applied to the system requirements by the design device 1, and further thereto, the order in which multiple conversion rules are applied to the system requirements by the design device 1. In particular, system design by the design device 1 may succeed or fail depending on the conversion rules applied to the system requirements, and further thereto, the order in which multiple conversion rules are applied to the system requirements. In other words, the purpose of the design device 1 is to concretize system requirements to a level allowing a system to be deployed.

In the present disclosure, in accordance with the configuration of a system to be determined as an outcome, a “component” may represent a configuration that has been maximally concretized to a level not further convertible to a concrete configuration, or may represent a configuration concretized to a desired level (for example, a function module for realizing a certain function). For this reason, the degree of concretization of each component is not uniquely defined. Additionally, a “component” may be defined, for example, in units such as a “server”, or may be defined more specifically, for example, in units such as a “CPU”, a “memory”, a “hard disk”, etc., or may be defined more roughly, for example, in units such as “system for performing facial authentication”, etc. For this reason, the units defining each component are not uniquely defined.

The design device 1 can also design systems by using the search tree indicated in FIG. 3. In this case, the design device 1 acquires system requirements for a design target. The system requirements are information describing configurations to be provided in an ICT system. Under the system requirements input to the design device 1, the configuration elements of the design target may be described abstractly. The design device 1 repeatedly applies predefined conversion rules to the acquired system requirements, thereby concretizing the system requirements to a level allowing the system to be deployed.

Specifically, the system requirements of the design target are configured to include one or more components. The design device 1 selects any one of the components included in the system requirements and applies a conversion rule for concretizing the selected component. The design device 1 performs system design by repeatedly selecting components and applying conversion rules. Due to this system design, conversion rules are applied to the components and the design target system is concretized in component units.

In the case in which this system design is always used, the design device 1 is required to, for each system requirement, generate and narrow down design proposals requiring a certain calculation time. Thus, there are cases in which higher-speed design due to calculation time reduction is sought while maintaining flexibility and saving labor.

The design device 1 can realize higher-speed design due to the configuration below.

### <Regarding Design Device 1>

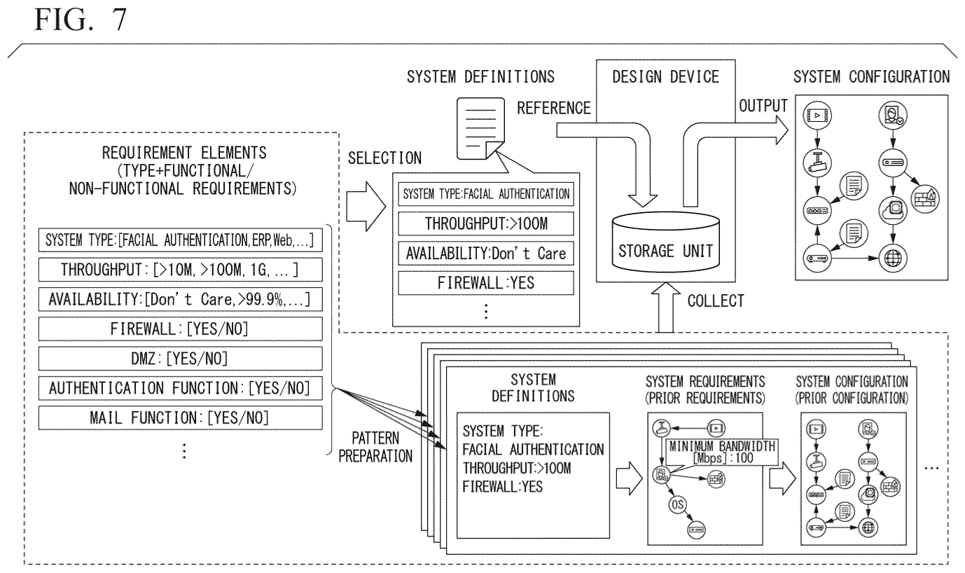

FIG. 7 is an explanatory diagram for schematically explaining the design device 1 according to the present embodiment.

Multiple system definitions can be input to the design device 1, for example, prior to designing a system. The system definitions are composed of groups composed, for example, of types representing the “requirement elements” on the left side of FIG. 7, and functional requirements or non-functional requirements relating to those types. By selecting a value of each of predefined requirement elements, a user can select desired system definitions to be input from among multiple system definitions that are groups of requirement elements that make up system requirements. Additionally, system requirements and a system configuration are associated in advance with each pattern of system definitions. In this case, a system configuration is a system configuration derived from the system requirements by applying a conversion series using a search tree. A set of these system definitions, system requirements, and a system configuration will also be referred to as “prior design information”. In the prior design information, the system requirements associated in advance with system definitions will also be referred to as “prior requirements” and the system configuration will also be referred to as a “prior configuration”.

The design device 1 collects prior design information. When system definitions for a design target are input, the design device 1 outputs (selects), from among prior design information that has been collected in advance, a system configuration corresponding to the input system definitions. As a result thereof, the design device 1 can perform higher-speed design by reducing the calculation time, while maintaining flexibility and saving labor.

Additionally, as described below, when the prior design information that has been collected in advance as mentioned above does not include prior design information having the system definitions of the design target, the design device 1 specifies system definitions (also referred to as “similar system definitions”) that are similar to the system definitions of the design target from among the system definitions in the prior design information that has been collected in advance. The design device 1 uses a system configuration (similar system configuration) corresponding to the specified similar system definitions to generate a new system configuration. In this case, the design device 1 outputs a new system configuration for the system definitions of the design target. Since the design device 1 generates a new system configuration using the similar system configuration, even in the case in which the system definitions in the design target are new, higher-speed design can be performed by reducing the calculation time in comparison with the case in which a similar system configuration is not used. Additionally, there are cases in which the design device 1 can perform more accurate design.

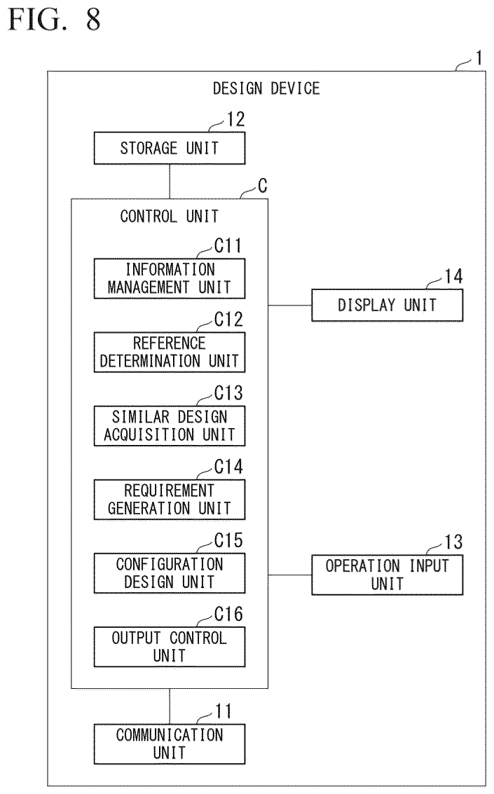

FIG. 8 is a schematic block diagram illustrating the configuration of a design device according to the present embodiment.

The design device 1 is configured to include a communication unit 11, a storage unit 12, an operation input unit 13, a control unit C, and a display unit 14.

The communication unit 11 communicates with other devices. For example, the communication unit 11 may receive, from another device, system requirements that are to be a design target.

The storage unit 12 stores various types of data. For example, the storage unit 12 stores requirement element information, requirement templates, prior design information, integrated data, conversion rules, and component evaluation models.

The requirement element information is a list of requirement elements. The integrated data, as described above, is information in which system requirements are associated with system configurations.

A requirement template is information in which system requirements are associated in advance with each of patterns of values and groups of requirement elements of system definitions.

The integrated data includes multiple conversion procedures from system requirements to system configurations, and system requirements before and after the respective conversion procedures. For example, the integrated data may be a trained model (see FIG. 3) that has undergone machine learning in advance, and may have configurations in which the order of application of conversion rules change in accordance with the results of machine learning.

The component evaluation models are information in which system requirements and evaluation values of the respective components in the system requirements have been associated in advance. For example, component evaluation models are trained models that, when system requirements are input, output evaluation values for respective components associated with those system requirements.

The storage unit 12 is configured by using a storage device provided in the design device 1. However, the storage unit 12 may be a storage device that is externally attached to the design device 1, or may be a storage device in another device connected by the communication unit 11.

The operation input unit 13 is, for example, an input device such as a keyboard or a mouse that receives user operations. For example, the operation input unit 13 receives user operations for inputting system definitions, or for providing instructions to start system design.

The control unit C controls various units in the design device 1 to perform various processes. The functions of the control unit C are executed by a CPU (Central Processing Unit) provided in the design device 1 reading out a program from the storage unit 12 and executing the program.

The display unit 14 is a display (the display 14 in FIG. 1) that displays various types of images based on the processing in the control unit C. For example, the display unit 14 displays the screen display in FIG. 2.

The main body 10 in FIG. 1 is configured to include the communication unit 11, the storage unit 12, and the control unit C. Other than the above, the design device 1 and the main body 10 may be provided with a microphone for inputting sound, a speaker for outputting sound, a camera for capturing images, etc.

The control unit C is configured to include an information management unit C11, a reference determination unit C12, a similar design acquisition unit C13, a requirement generation unit C14, a configuration design unit C15, and an output control unit C16.

The information management unit C11 acquires and pre-stores, in the storage unit 12, requirement element information, prior design information, integrated data, conversion rules, and component evaluation models. The information management unit C11 may acquire some or all of the information from the respective units in the design device 1, or may acquire the information from devices other than the design device 1.

The reference determination unit C12, based on input system definitions (also referred to as “input system definitions”) for a design target and system definitions (prior definitions) in prior design information, determines which system configuration is to be output as the system configuration of the design target. Specifically, the reference determination unit C12 determines whether to output a prior configuration corresponding to the prior definitions, or to generate and output a new system configuration. In the case in which it is determined that a prior configuration is to be output, the reference determination unit C12 displays on the display unit 14, as the system configuration for the system definitions of the design target, the prior configuration corresponding to the prior definitions.

In the case in which a prior definition matching an input system definition does not exist, the similar design acquisition unit C13 selects prior definitions (similar system definitions) similar to the input system definitions from the prior design information. The similar design acquisition unit C13 acquires prior design information (referred to as “similar design information”) including the similar system definitions that have been selected.

The process performed by the similar design acquisition unit C1 will also be referred to as a similar design selection process.

The requirement generation unit C14 extracts system requirements based on input system definitions and requirement templates. The requirement generation unit C14 displays the extracted system requirements on the display unit 14 as system requirements to be edited, and receives edits to components by the user. The editing of components includes, for example, the addition, deletion, and change of nodes, edges, or property information thereof. The requirement generation unit C14 generates new system requirements based on the editing results. The process performed by the requirement generation unit C14 will also be referred to as a requirement generation process.

The requirement generation unit C14 may also display and have a user edit prior requirements (also referred to as “similar system requirements”) included in similar design information as system requirements to be edited. Additionally, the requirement generation unit C14 may have the user edit the system requirements from the beginning (in a state absent of components) without displaying system requirements to be edited. Additionally, the input system definitions may be obtained by a user selecting values and groups of requirement elements.

The configuration design unit C15 receives, as an input, new system requirements (also referred to as “input system requirements”) edited with the requirement generation unit C14, and generates a new system configuration based on similar design information, integrated data, conversion rules, and component evaluation models. The configuration design unit C15 displays the new system configuration that has been generated, as a system configuration corresponding to the system definitions of the design target, on the display unit 14. The process performed by the configuration design unit C15 will also be referred to as a configuration design process.

The output control unit C16 displays various types of images on the display unit 14 based on the processes in the respective units in the control unit C. For example, the output control unit C16 generates and displays, on the display unit 14, data for a screen display of system definitions or a system configuration (see FIG. 2), or for a screen display for editing system requirements. The output control unit C16 may generate data (for example, HTML) for a display image and may output the data to another device. In this case, the other device may display the display image on a display, or may output the display image by printing, etc.

Hereinafter, the similar design selection process, the requirement generation process, and the configuration design process (these processes will also be referred to as “design processes”) will be explained.

### <Similar Design Selection Process>

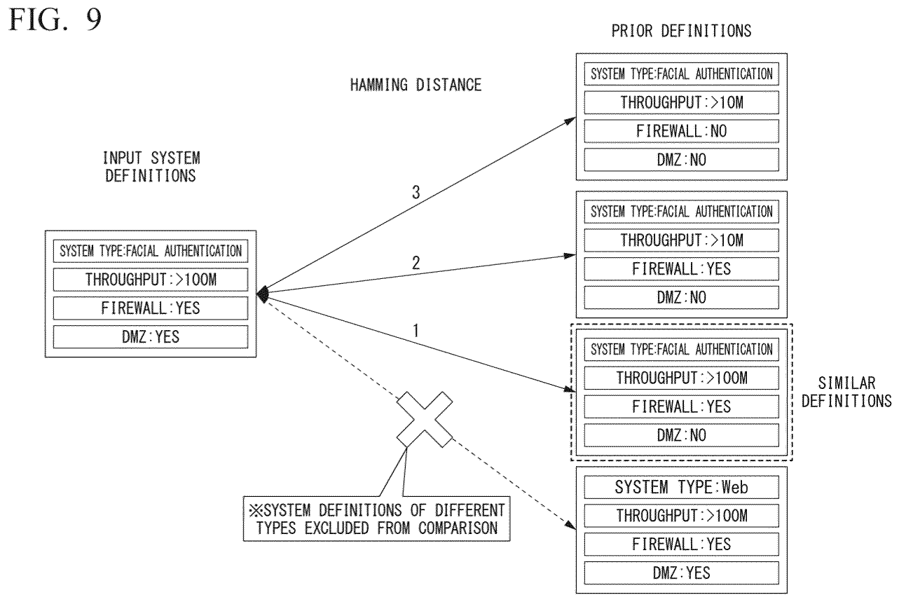

FIG. 9 is a diagram illustrating an example of a similar design selection process according to the present embodiment.

The design device 1 determines whether or not a design (system requirements or a system configuration) is identical or similar by comparing system definitions. The similar design acquisition unit C13 references the system type of an input system definition and extracts prior definitions including the same system type. The similar design acquisition unit C13 calculates the Hamming distances between values and requirement elements of the extracted prior definitions and the input system definitions. The similar design acquisition unit C13 selects, as similar system definitions, the prior definitions for which the calculated Hamming distances are the smallest.

The similar design acquisition unit C13 excludes prior definitions for different system types from being compared because, in the case in which the system type is different, the system requirements may differ significantly. Thus, in the similar design selection process, the similar design acquisition unit C13 may require the values of some of the requirement elements to match.

### <Requirement Generation Process>

FIG. 10 is a diagram illustrating a requirement generation process according to the present embodiment.

In a requirement template, system requirements are associated with each pattern of values and groups of requirement elements in the system definitions. The requirement generation unit C14 extracts, from the requirement template, system requirements matching the values and groups of requirement elements of the input system definitions. The extracted system requirements are displayed as system requirements to be edited, and components represented by these system requirements can be edited by the user.

In the example in this drawing, the user performs editing to add property information for the nodes and to add components. Specifically, the user adds the property information “Minimum bandwidth 100 Mbps” to a node representing facial authentication. Additionally, the user adds a node representing a firewall and adds an edge (arrow) having the node representing facial authentication as the starting point. As a result of these editing operations, the node N301 representing a firewall, the edge E302 serving as the endpoint of this node, and property information for the node representing facial authentication are added to the system requirements.

### <Configuration Design Process>

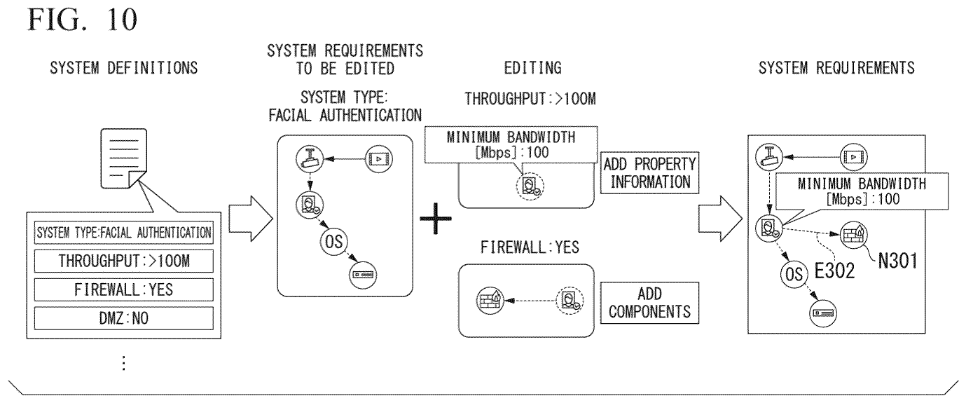

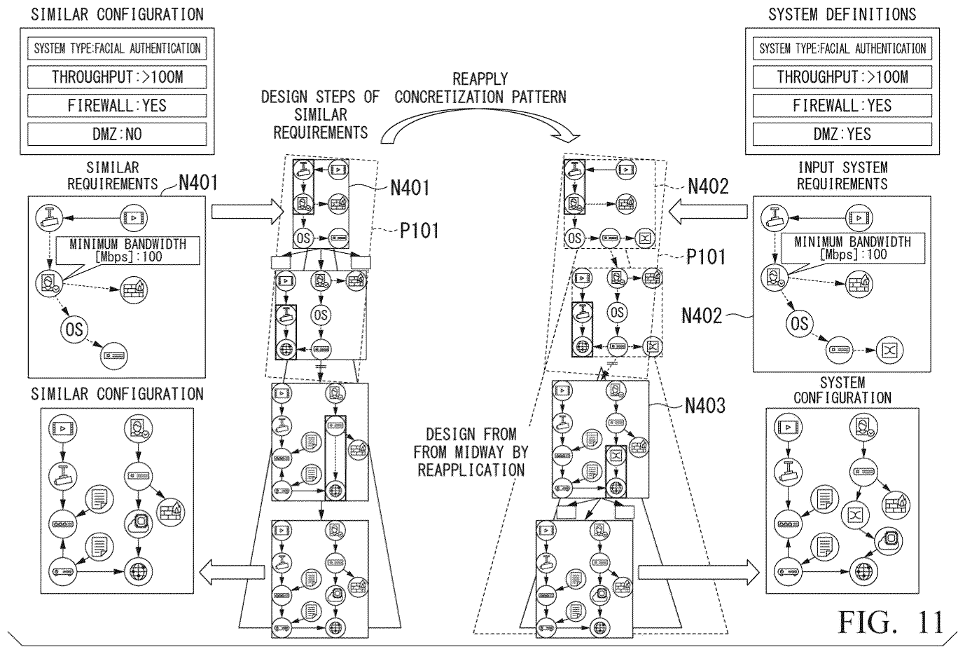

FIG. 11 is a diagram illustrating an example of a configuration design process according to the present embodiment.

The design device 1 reduces the processing for generating a system configuration by reapplying, to input system requirements, a portion of a conversion series (also referred to as “reapplied conversion series”) for a similar system configuration, thereby increasing the processing speed.

The configuration design unit C15 references integrated data in a similar system configuration and extracts, for a conversion series from a similar system configuration to a similar system configuration, the system requirements (the nodes in FIG. 3) before and after conversion, conversion rules, and evaluation values (this information will also be referred to as “concretization patterns”; the evaluation values will be described below). The configuration design unit C15 identifies, for input system requirements, system requirements to which a concretization pattern of a similar system configuration can be applied. Specifically, the configuration design unit C15 determines whether or not there are target components to which conversion rules have been applied in accordance with the order of the conversion series of the similar system configuration. The configuration design unit C15 identifies, as a “new design starting point”, system requirements for which there are no such target components, and identifies the preceding system requirements as a “reapplication endpoint”.

In this case, the target components are, for example, any of nodes, edges, or properties, or combinations thereof, and are prestored in the integrated data. An example of a combination is a target component including two nodes and an edge having these nodes as a starting point and an endpoint.

The example in FIG. 11 indicates that the configuration design unit C15 has determined that the reapplied conversion series P101 in the similar system configuration N401 can be reapplied to the input system requirements N402, and that a new design starting point N403 has been identified. The design device 1 generates a system configuration by performing a configuration generation process on the system requirements at the new design starting point N403.

Thus, the design device 1 generates (designs) a system configuration from system requirements that cannot be applied by reapplying a concretization pattern (conversion series) of a similar system configuration. As a result thereof, the design device 1 can reduce the processing for generating a system configuration in comparison with the case in which a system configuration is generated from input system requirements, thereby further increasing the processing speed.

### <Processing Flow>

Hereinafter, the processing flow in the design device 1 will be explained.

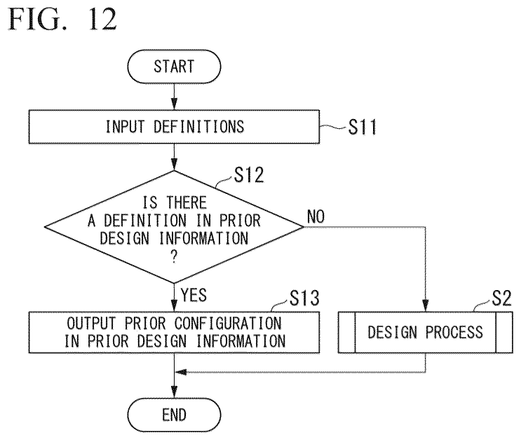

FIG. 12 is a flow chart illustrating the processing in the design device 1 according to the present embodiment.

System definitions for a design target (input system definitions) are input to the design device 1 (S11). The reference determination unit C12 determines whether or not the system definitions that were input in S11 are included in prior design information stored in the storage unit 12, i.e., whether or not they match prior definitions (S12). In the case in which there is such prior design information (step S12: YES), the display unit 14 outputs the prior configuration for that prior design information (step S13). Meanwhile, in the case in which there is no such prior design information (step S12: NO), the design device 1 performs a design process (step S2).

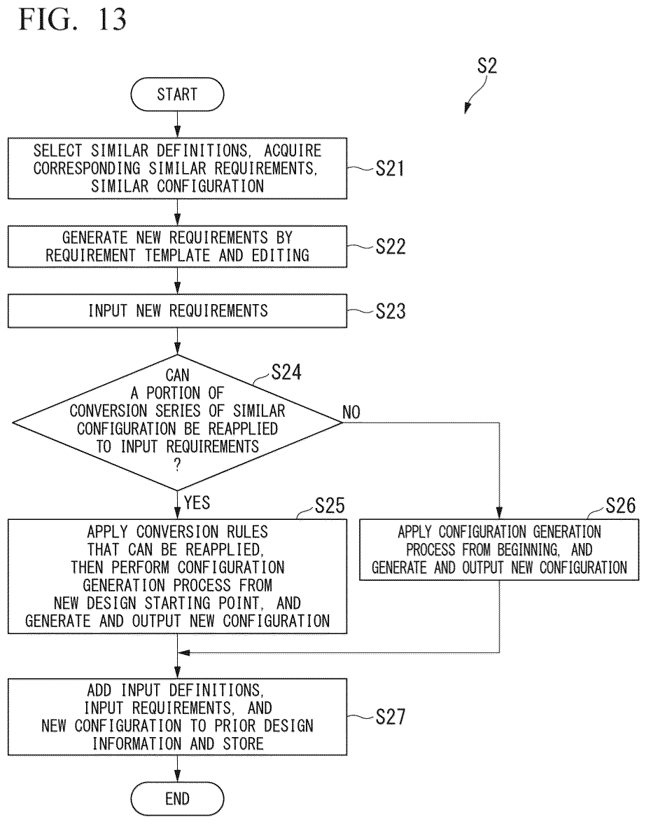

FIG. 13 is a flow chart indicating a design process according to the present embodiment. The design process is the process of step S2 in FIG. 12.

The similar design acquisition unit C13 selects, from the prior design information, similar system definitions that are similar to the input system definitions. The similar design acquisition unit C13 acquires similar design information including the selected similar system definitions, i.e., similar system requirements and a similar system configuration corresponding to the similar system definitions (step S21).

The requirement generation unit C14 extracts system requirements corresponding to the input system definitions in a requirement template, and receives edits to the components by the user. The requirement generation unit C14 generates new system requirements based on the editing results (step S22).

The new system requirements (input system requirements) generated in step S22 are input to the configuration design unit C15 (step S23).

The configuration design unit C15 determines whether or not a portion of the conversion series of a similar system configuration can be reapplied to the input system requirements, i.e., whether or not there are target components to which conversion rules have been applied in accordance with the order of the conversion series in the similar system configuration (step S24).

In the case in which a portion of the conversion series of a similar system configuration can be reapplied (step S24: YES), the configuration design unit C15 applies the conversion rules of the conversion series of the similar system configuration up to the reapplication endpoint. Then, the configuration design unit C15 performs a configuration generation process from the new design starting point, and as a result thereof, generates and outputs a new configuration (step S25). Meanwhile, in the case in which a portion of a conversion series of a similar system configuration cannot be reapplied (step S24: NO), the configuration design unit C15 performs a configuration generation process from the input system requirements, and as a result thereof, generates and outputs a new configuration (step S26). The outputs in step S25 and step S26 refer, for example, to the configuration design unit C15 displaying, on the display unit 14, the new system configuration that has been generated, as a system configuration corresponding to the system definitions of the design target.

The information management unit C11 adds and stores, as prior design information in the storage unit 12, the input system definitions in S11 (FIG. 12), the input system requirements in S24, and the new system configuration generated in step S25 or step S26.

### <Processing in Configuration Design Unit>

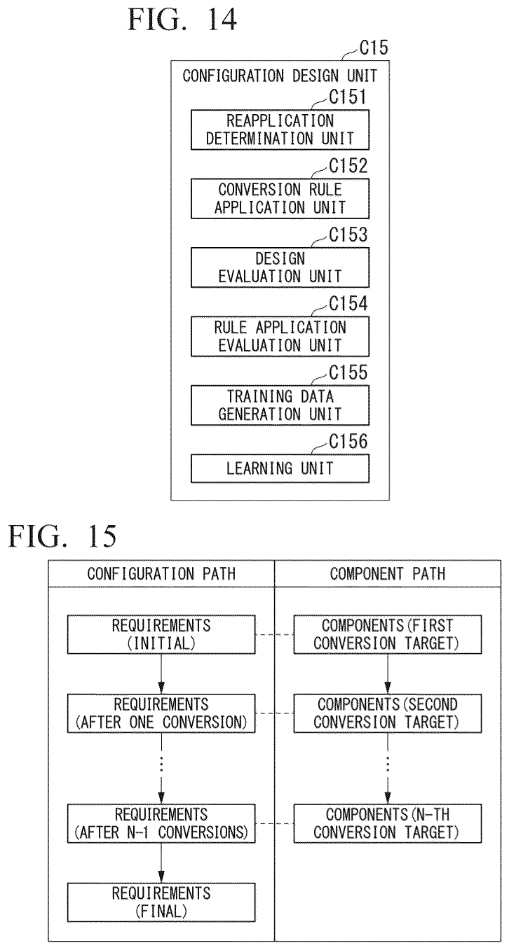

FIG. 14 is a schematic block diagram illustrating the configuration of the configuration design unit C15 according to the present embodiment. The configuration design unit C15 is configured to include a reapplication determination unit C151, a conversion rule application unit C152, a design evaluation unit C153, a rule application evaluation unit C154, a training data generation unit C155, and a learning unit C156.

The reapplication determination unit C151 determines whether or not a portion of a conversion series of a similar system configuration can be reapplied to system requirements. In the case in which it is determined that reapplication is possible, the configuration design unit C15 applies to the input system requirements, up to the reapplication endpoint, the conversion rules of the conversion series of the similar system configuration. Thereafter, the configuration design unit C15 outputs, to the conversion rule application unit C152, the concretization pattern up to the reapplication endpoint, and the system requirements at the new design starting point. Meanwhile, in the case in which it is determined that reapplication is not possible, the input system requirements are output to the conversion rule application unit C152.

The conversion rule application unit C152 performs system design by repeatedly applying conversion rules to components represented by the input system requirements until design results for that system design are obtained.

System design success (successfully designing a system) includes obtaining system requirements concretized to a level allowing the system to be deployed. System design failure (failing to design a system) includes establishing that system requirements concretized to a level allowing the system to be deployed cannot be obtained. For example, in the case in which system requirements are not concretized to a level allowing the system to be deployed and there are no conversion rules that are applicable to the system requirements, the conversion rule application unit C152 determines that the system design has failed.

Additionally, depending on the conversion rules, there may be situations in which the application of conversion rules to system requirements results in a loop. Even in the case in which conversion rules are applicable to system requirements, in the case in which there are no conversion series (application of one or more conversion rules) that do not form a loop, the conversion rule application unit C152 determines that the system design has failed.

In the case in which the conversion rule application unit C152 has not successfully designed a system even after repeatedly applying conversion rules for system design a prescribed number of times, it may be determined that the system design has failed. That is, system design failure may include not being able to successfully design a system even after repeatedly applying conversion rules for system design a prescribed number of times.

The conversion rule application unit C152 generates system design history information when performing system design. The history information generated by the conversion rule application unit C152 is used for determining evaluation values for system requirements and evaluation values for components included in the system requirements, and for generating training data.

FIG. 15 is a diagram illustrating an example of history information according to the present embodiment. In the example in FIG. 15, the conversion rule application unit C152 generates a configuration path and a component path as system design history information.

The configuration path indicates a chronological sequence of system requirements obtained each time conversion rules were applied, from the initial system requirements to the final system requirements. The initial system requirements mentioned here are the input system requirements.

The final system requirements mentioned here are the system requirements obtained as design results of the system design, i.e., the system configuration. The design results of the system design mentioned here can be considered to be results of some sort that can be evaluated regarding system design. Hereinafter, examples of cases in which system design success or failure results are obtained as design results will be explained. However, there is no limitation thereto.

In the example in FIG. 15, the number of times that conversion rules were applied until the final system requirements were obtained from the initial system requirements is represented by N. N is a positive integer.

In the example in FIG. 15, the configuration path is configured as chronological data for N+1 system requirements. The component path is configured as chronological data for N components.

The i-th converted component indicated in the component path is included in the i-th system requirements in chronological order in the configuration path. In this case, i is an integer such that 1≤i≤N.

The final system requirements correspond to the system requirements obtained after applying conversion rules N times. Since the final system requirements yield system design success or failure results, the design evaluation unit C153 can determine evaluation values for a single system design. For example, in the case in which the system design result is a success, the design evaluation unit C153 may set the evaluation value of the single system design to be 1, and in the case in which the system design result is a failure, the evaluation value of the single system design may be set to be 0.

The series of repeated operations of selecting components and applying conversion rules from the initial system requirements to the final system requirements will be referred to as a a single system design, or simply as a system design.

The conversion rule application unit C152 may generate, as system design history information, history information indicating a history of conversion rules that have been applied in addition to the history of system requirements and the history of components to which the conversion rules have been applied.

The design evaluation unit C153 determines evaluation values for system designs based on the design results of system designs. As described above, in the case in which the conversion rule application unit C152 has succeeded in system design, the design evaluation unit C153 may determine the evaluation result of the system design to be 1. In the case in which the conversion rule application unit C152 has failed in system design, the design evaluation unit C153 may determine the evaluation value of the system design to be 0.

In addition to the results of success or failure of system design, in the case in which the conversion rule application unit C152 has succeeded in system design, the design evaluation unit C153 may determine an evaluation for the system design based on obtained evaluation indicator values for the system. As the evaluation indicator values for the system in this case, various types of evaluation indicator values can be used. For example, the design evaluation unit C153 may use a system processing speed evaluation indicator value, a reliability evaluation indicator value, a construction cost evaluation indicator value, an operating cost evaluation indicator value, or a combination thereof. However, there is no limitation thereto.

The design evaluation unit C153 may pre-store computational expressions for computing evaluation indicator values of systems based on the components used in the systems. Alternatively, the design evaluation unit C153 may acquire in advance, by training, a model that outputs system evaluation indicator values in response to the input of system requirements.

The rule application evaluation unit C154 determines evaluation values regarding conversion to individual components in system designs based on evaluation values for the system designs. Specifically, the rule application evaluation unit C154 determines, for each component, an evaluation value regarding component conversion based on data integrating multiple system design histories for the same component. The data integrating multiple system design histories for the same component is integrated data (see FIG. 3).

In the case in which concretization patterns have been input to the conversion rule application unit C152, the integrated data also includes those concretization patterns.

FIG. 16 is a diagram illustrating association relationships in integrated data according to the present embodiment. This diagram indicates the relationships between the system requirements in FIG. 3 and the system requirements after the conversion rule has been applied once. In this diagram, as in FIG. 3, the system requirements correspond to nodes.

In the example in FIG. 16, the system requirements before applying the conversion rules are provided with three components P11, P12, and P13. Three conversion rules R11, R12, and R13 can be applied to the component P11. A single conversion rule R14 can be applied to the component P12. Two conversion rules R15 and R16 can be applied to the component P13.

As mentioned above, the edges in the integrated data are directed edges indicating conversion rules. The starting ends (the ends on the starting point side) of these directed edges are connected to nodes indicating the system requirements before conversion, and the ending edges (the ends on the endpoint side) are connected to nodes indicating the system requirements after conversion.

Additionally, the edges emerging from a single node are grouped by components included in the system requirements indicated by that node, as illustrated in FIG. 16. These groupings may also be indicated in the integrated data. For example, as indicated in FIG. 16, grouping may be indicated by indicating the components that are configuration requirements in the nodes in the integrated data, and connecting the starting points of edges to any of the components.

Neither the number of components provided in the system requirements nor the number of conversion rules applicable to one component is limited to a specific number. The number of components provided by the system requirements may differ before and after application of conversion rules. The number of conversion rules that are applicable to components may also differ for each component.

Additionally, in the example in FIG. 16, the configuration design unit C15 is indicated as computing evaluation values for system requirements and evaluation values for each component in the system requirements.

The evaluation values for system requirements are written into the nodes in the integrated data.

Meanwhile, the evaluation value for each component in the system requirements is computed at the time of generation of training data and is incorporated into the training data.

There is no need to provide the nodes in integrated data with storage areas for evaluation values of components in the system requirements.

The training data generation unit C155 generates training data for training a component evaluation model. In particular, the training data generation unit C155 generates training data including evaluation values regarding the conversion of components. Specifically, the training data generation unit C155 generates training data including system requirements, one component among the components included in the system requirements, and an evaluation value for that component in the system requirements.

The learning unit C156 is trained regarding the selection of components to which conversion rules are applied based on training data including evaluation values regarding the conversion of components, generated by the training data generation unit C155. Specifically, the learning unit C156 learns a component evaluation model.

The learning unit C156 corresponds to an example of learning means.

Alternatively, in the case in which conversion rules are pre-defined in common for the system design performed by the configuration design unit C15, the learning unit C156 may be trained regarding the selection of conversion rules to be applied to the system requirements. That is, the learning unit C156 may also be trained regarding the selection of conversion rules that are applicable to components that are further divided from the selection of the components included in the system requirements. Specifically, the learning unit C156 may learn a conversion rule evaluation model that receives inputs of system requirements and that outputs an evaluation value for each conversion rule that is applicable to those system requirements.

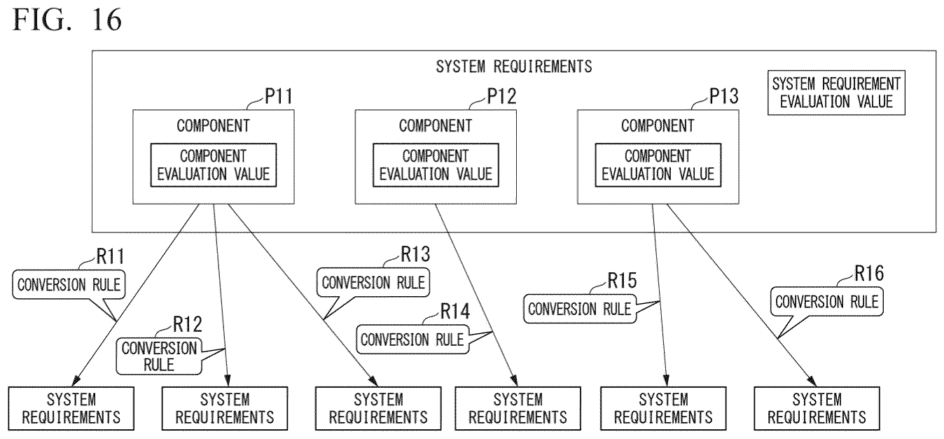

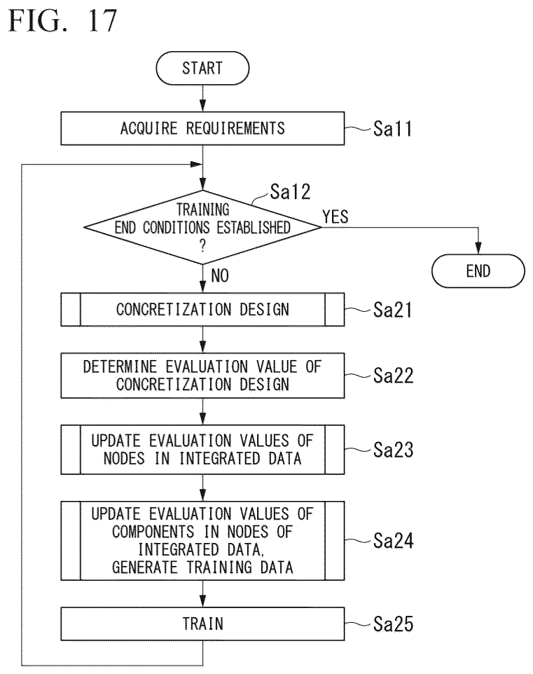

FIG. 17 is a flow chart indicating an example of a configuration generation process according to an embodiment. This flow chart indicates the procedure for a configuration generation process, and indicates the processing procedure by which the configuration design unit C15 generates training data and implements training.

In the process in FIG. 17, the configuration design unit C15 acquires system requirements to be learned (step Sa11). The configuration design unit C15 may use, as the system requirements to be learned, the system requirements provided as the system requirements of design targets. Alternatively, the configuration design unit C15 may acquire system requirements to be learned separately from the system requirements of design targets.

Next, the control unit C determines whether or not training end conditions are established (step Sa12). The training end conditions may be based on the training time, the training number (the number of times the loop from step Sa12 to S24 has been repeated), the size of the training error, etc. However, there is no limitation thereto.

In the case in which the control unit C has determined that the end conditions are established (step Sa12: YES), the configuration design unit C15 ends the process in FIG. 17.

On the other hand, in the case in which the control unit C has determined that the end conditions are not established (step Sa12: NO), the conversion rule application unit C152 performs system design on the system requirements to be learned (step Sa21). Specifically, the conversion rule application unit C152 repeatedly applies conversion rules to the system requirements to be learned until system design success or failure results are obtained. During the system design, the conversion rule application unit C152 generates a configuration path and a component path. Additionally, when there are no nodes in the integrated data indicating system requirements that have arisen in the system design, the conversion rule application unit C152 adds, to the integrated data, a node indicating the system requirements that have arisen in the system design.

The process in step Sa21 will also be referred to as a “concretization design process”.

FIG. 17 shows an example of the case in which the configuration design unit C15 acquires multiple system requirements in step Sa11, and implements design for each system requirement in step Sa21. Alternatively, instead of acquiring system requirements in step Sa11, the configuration design unit C15 may acquire one system requirement each time step Sa21 is executed, and may perform system design for the acquired system requirement.

Additionally, the configuration design unit C15 may perform system design on a different system requirement each time the process in step Sa21 is performed. Alternatively, the configuration design unit C15 may perform system design on a system requirement that is the same as a system requirement for which system design has previously performed by the process in step Sa21 by using a conversion series different from the conversion series used in the design in the previous step Sa21.

Next, the design evaluation unit C153 determines an evaluation value for the system design performed by the conversion rule application unit C152 (step Sa22).

For example, based on whether the conversion rule application unit C152 has succeeded or failed in system design, the design evaluation unit C153 may set the evaluation value for the system design to be 1 in the case in which the system design has succeeded, and may set the evaluation value for the system design to be 0 in the case in which the system design has failed. Alternatively, in the case in which the conversion rule application unit C152 has succeeded in system design, the design evaluation unit C153 may determine an evaluation value for the system design based on an evaluation value of the system that has been obtained.

Next, the rule application evaluation unit C154 updates the evaluation values for nodes in the integrated data based on the evaluation values of the system design determined in step Sa22 (step Sa23). For example, the rule application evaluation unit C154 determines the evaluation values of a node in the integrated data to be the highest evaluation value (the evaluation value for which the evaluation is the highest) among the evaluation values of child nodes to that node. The process in step Sa23 will also be referred to as a “node evaluation process”.

Next, the rule application evaluation unit C154 determines evaluation values of components included in the system requirements and determines evaluation values for the respective components in the component path, and the training data generation unit C155 generates and saves training data (step Sa24). The process in step Sa24 will also be referred to as a “training data generation process”.

Furthermore, the learning unit C156 uses the training data generated by the training data generation unit C155 to train the component evaluation model (step Sa25). As mentioned above, the component evaluation model is a model that, in response to the input of system requirements, outputs an evaluation for each component indicated by those system requirements.

After step Sa25, the process returns to step Sa12.

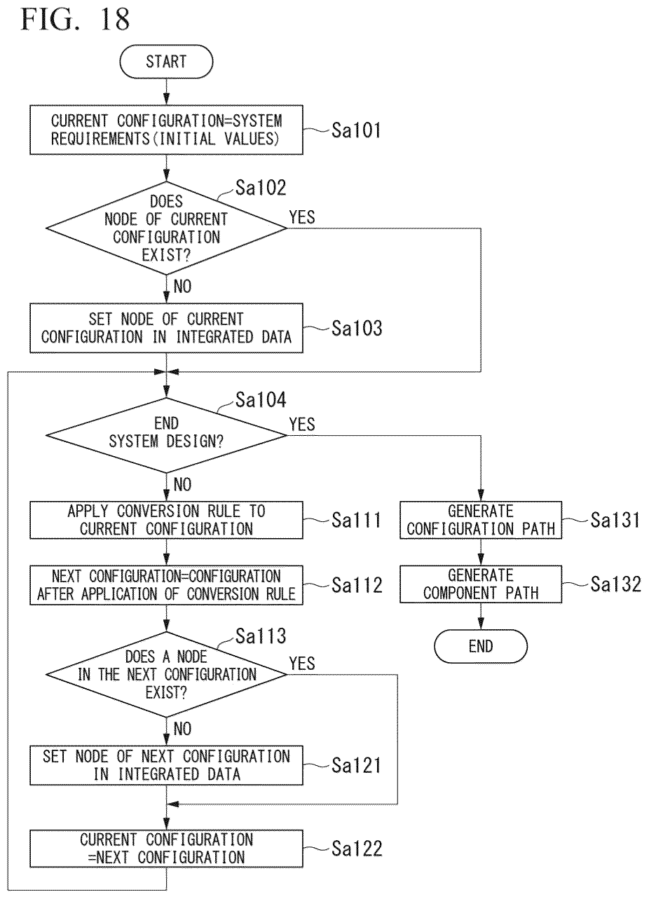

FIG. 18 is a flow chart indicating an example of a concretization design process according to the present embodiment.

The configuration design unit C15 performs the process in FIG. 18 as step Sa21 in FIG. 17. As mentioned above regarding step Sa21 in FIG. 17, the configuration design unit C15 generates a configuration path and a component path during system design or sets integrated data nodes.

In the process in FIG. 18, a “current configuration” variable and a “next configuration” variable are used as variables for the values of the system requirements. The system requirements indicated as values of the “current configuration” variables are denoted by “current configuration”. The system requirements indicated as values of the “next configuration” variables are denoted by “next configuration”.

In the process in FIG. 18, the conversion rule application unit C152 stores system requirements received in step Sa11 in FIG. 17 as “current configuration” variables (step Sa101). That is, the conversion rule application unit C152 sets, as initial values of the “current configuration” variables, the system requirements received in step Sa11 in FIG. 17.

Next, the conversion rule application unit C152 determines whether or not the “current configuration” is registered as a node in the integrated data (step Sa102). For example, the conversion rule application unit C152 compares the system requirements indicated by each node in the integrated data with the “current configuration”.

If it is determined that the “current configuration” is not registered as a node in the integrated data (step Sa102: NO), the conversion rule application unit C152 registers the “current configuration” as a node in the integrated data (step Sa103). Registering system requirements as a node in integrated data means newly providing a node indicating those system requirements. Next, the conversion rule application unit C152 determines whether or not system design ending conditions are established (step Sa104). For example, the conversion rule application unit C152 may determine that the system design ending conditions are established if there is not a single concretization rule that can be applied to the “current configuration” or if the “current configuration” is concretized to a deployable level.

If it is determined that the ending conditions are not established (step Sa104: NO), the conversion rule application unit C152 selects one component to be concretized from the “current configuration” and applies a conversion rule thereto (step Sa111). The conversion rule application unit C152 concretizes the component by applying the conversion rule.

The conversion rule application unit C152 stores the system requirements resulting after applying the conversion rule in step Sa111 as “next configuration” variables (step Sa112).

Next, the conversion rule application unit C152 determines whether or not the “next configuration” is registered as a node in the integrated data (step Sa113). For example, the conversion rule application unit C152 compares the system requirements indicated by each node in the integrated data with the “next configuration”. If it is determined that the “next configuration” is not registered as a node in the integrated data (step Sa113: NO), the conversion rule application unit C152 registers the “next configuration” as a node in the integrated data (step Sa121). Specifically, the conversion rule application unit C152 provides a node indicating the “next configuration” in the integrated data. Then, the conversion rule application unit C152 establishes, in the integrated data, an edge between nodes such that a node indicating the “current configuration” is a parent node, and a node indicating the “next configuration” is a child node. This edge represents the application of the conversion rule in step Sa111.

Then, the conversion rule application unit C152 stores the “next configuration” as the “current configuration” variable (step Sa122).

After step Sa122, the process shifts to step Sa104.

Meanwhile, in step Sa113, if the conversion rule application unit C152 has determined that the “next configuration” is registered as a node in the integrated data (step Sa113: YES), the process shifts to step Sa122. Therefore, in this case, the conversion rule application unit C152 does not perform a process for setting a node in the integrated data in step Sa121.

On the other hand, if it is determined that the ending conditions are established in step Sa104 (step Sa104: YES), the conversion rule application unit C152 defines the system requirements that arose in the current process in FIG. 18, arranged chronologically, as a configuration path (step Sa131). Furthermore, the conversion rule application unit C152 defines, as a component path, the components selected for application of the conversion rule in step Sa11 among the components included in the system requirements in the configuration path, arranged chronologically, as a component path (step Sa132).

After step Sa132, the configuration design unit C15 ends the process in FIG. 18.

On the other hand, if the conversion rule application unit C152 has determined, in step Sa102, that the “current configuration” is already registered as a node in the integrated data, the process shifts to step Sa104. Therefore, in this case, the conversion rule application unit C152 does not perform the process for setting a node in the integrated data in step Sa103.

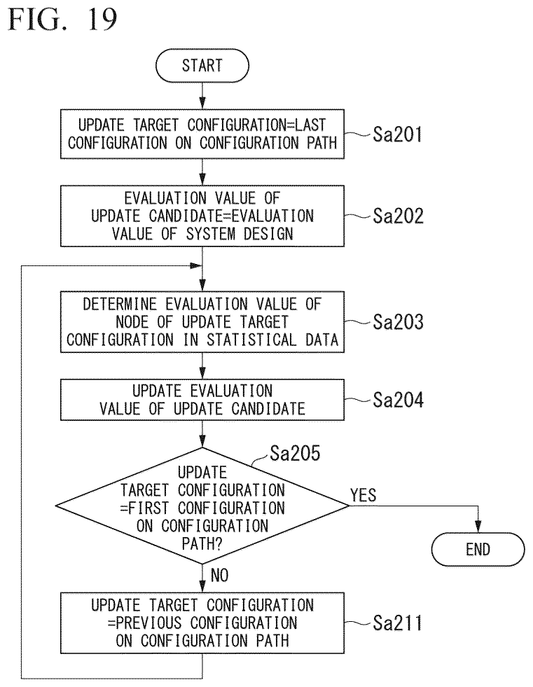

FIG. 19 is a flow chart indicating an example of a node evaluation process according to the present embodiment. This flow chart indicates an example of a processing procedure for the configuration design unit C15 to update evaluation values indicated in nodes of the integrated data. The configuration design unit C15 performs the process in FIG. 19 as step Sa23 in FIG. 17.

In the process in FIG. 19, an “update candidate evaluation value” variable is used as a variable taking the values of the evaluation values in the system requirements. Additionally, in the process in FIG. 19, an “update target configuration” variable is used as a variable taking the value of a pointer designating any one of the system requirements included in a configuration path. The evaluation value indicated as the value of the “update candidate evaluation value” variable is denoted as an “update candidate evaluation value”. The system requirements designated by the value of the “update target configuration” variable is denoted as the “update target configuration”.

In the process in FIG. 19, the rule application evaluation unit C154 defines, as an “update target configuration”, the system requirements indicated by the last node in the configuration path (step Sa201). That is, the rule application evaluation unit C154 sets the value of the “update target configuration” variable so that the value of the “update target configuration” variable designates the last node on the configuration path. The nodes on the configuration path are individual system requirements included on the configuration path.

Additionally, the rule application evaluation unit C154 sets the initial value of the “update candidate evaluation value” variable to be the system design evaluation value determined in step Sa22 in FIG. 17 (step Sa202).

Next, the rule application evaluation unit C154 determines an evaluation value for the node representing the “update target configuration” in the integrated data (step Sa203). The evaluation value for a node in the integrated data is the evaluation value for the system requirement indicated by that node.

Specifically, the rule application evaluation unit C154 compares the evaluation value of the node representing the “update target configuration” in the integrated data with the “update candidate evaluation value”. If the “update candidate evaluation value” is larger, the rule application evaluation unit C154 updates the evaluation value of the node representing the “update target configuration” in the integrated data to the “update candidate evaluation value”. Meanwhile, if the evaluation value of the node representing the “update target configuration” in the integrated data is larger, then the rule application evaluation unit C154 keeps the evaluation value of the node representing the “update target configuration” in the integrated data unchanged.

If an evaluation value has not been set for a node, the rule application evaluation unit C154 performs the process by assuming that the value 0 is set as the evaluation value of that node.

Next, the rule application evaluation unit C154 updates the value of the “update candidate evaluation value” (step Sa204). Specifically, the rule application evaluation unit C154 sets, as the “update candidate evaluation value”, the value determined to be the evaluation value of the node representing the “update target configuration” in the integrated data in step Sa203.

Next, the rule application evaluation unit C154 determines whether or not the “update target configuration” is the first system requirements of the configuration path (step Sa205).

If the rule application evaluation unit C154 has determined that the “update target configuration” is the first system requirements of the configuration path (step Sa205: YES), the configuration design unit C15 ends the process in FIG. 19.

On the other hand, if it is determined that the “update target configuration” is not the first system requirements of the configuration path (step Sa205: NO), the rule application evaluation unit C154 defines the system requirements preceding the “update target configuration” on the configuration path to be the “update target configuration” (step Sa211).

After step Sa211, the process returns to step Sa203.

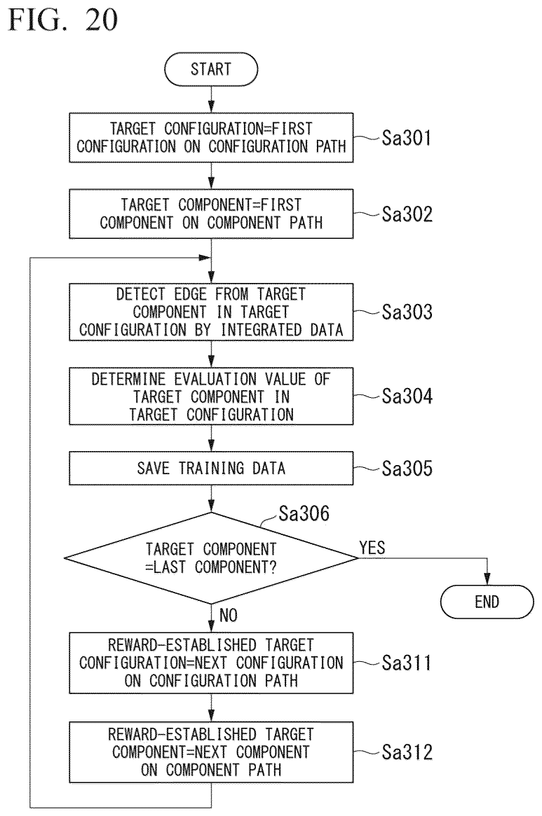

FIG. 20 is a flow chart indicating an example of a training data generation process according to the present embodiment. This flow chart indicates an example of a processing procedure by which the configuration design unit C15 generates training data. The configuration design unit C15 performs the process in FIG. 20 as step Sa24 in FIG. 17.

In FIG. 20, the “target configuration” variable is used as a variable taking the value of a pointer designating any of the system requirements in the configuration path. Additionally, in the process in FIG. 20, a “target component” variable is used as a variable taking the value of a pointer designating any of the components in the component path. The system requirements indicated as the value of the “target configuration” variable are denoted as a “target configuration”. The component indicated as the value of the “target component” variable is denoted as a “target component”.

In the process in FIG. 20, the training data generation unit C155 defines the first system requirements of the configuration path to be the “target configuration” (step Sa301). That is, the training data generation unit C155 sets the value of the “target configuration” variable so that the value of the “target configuration” variable designates the first system requirements of the configuration path.

Next, the training data generation unit C155 defines the first component of the component path to be the “target component” (step Sa302). That is, the training data generation unit C155 sets the value of the “target component” variable so that the value of the “target component” variable designates the first component on the component path.

Furthermore, the training data generation unit C155 lists all of the directed edges grouped with the “target component” among the directed edges having, as starting points, nodes represented by the “target configuration” in the integrated data (step Sa303).

The training data generation unit C155 defines, as the evaluation value of the “target component”, the highest value among the evaluation values recorded in the endpoint nodes of the respective directed edges listed in step Sa303 (step Sa304).

Additionally, the training data generation unit C155 generates, as training data, a group of the “target configuration”, the “target component”, and the evaluation value of the “target component” determined in step Sa304, and the generated training data is stored in the storage unit 12 (step Sa305).

Additionally, the training data generation unit C155 determines whether or not the “target component” is the last component on the component path (step Sa306). That is, the training data generation unit C155 determines whether or not the value of the “target component” variable designates the last component on the component path.

If it is determined that the “target component” is not the last component on the component path (step Sa306: NO), the training data generation unit C155 defines the component immediately following the “target component” on the component path to be the “target component” (step Sa311). That is, the training data generation unit C155 updates the value of the “target component” variable to designate the component that is immediately next in the component path.

Additionally, the training data generation unit C155 defines the system requirements immediately following the “target configuration” on the configuration path to be the “target configuration” (step Sa312). That is, the training data generation unit C155 updates the value of the “target configuration” variable to designate the system requirements that are immediately next on the configuration path.

After step Sa312, the process shifts to step Sa303.

On the other hand, if it is determined that the “target component” is the last component on the component path in step Sa306 (step Sa306: NO), the configuration design unit C15 ends the process in FIG. 20. In this case, the process shifts to step Sa25 in FIG. 17.

If the component path is empty at the time step Sa24 in FIG. 17 is started, the configuration design unit C15 skips the process in step Sa24. In this case, the configuration design unit C15 does not perform the process in FIG. 20.

In step Sa25 in FIG. 17, the learning unit C156 uses each of the training data generated by the training data generation unit C155 to train the component evaluation model.

In this training, the learning unit C156 updates the parameter values of the component evaluation model so that, when the system requirements indicated in the training data are input to the component evaluation model, the evaluation values output by the component evaluation model regarding the components indicated in the training data approach the evaluation values of the components indicated by the training data.

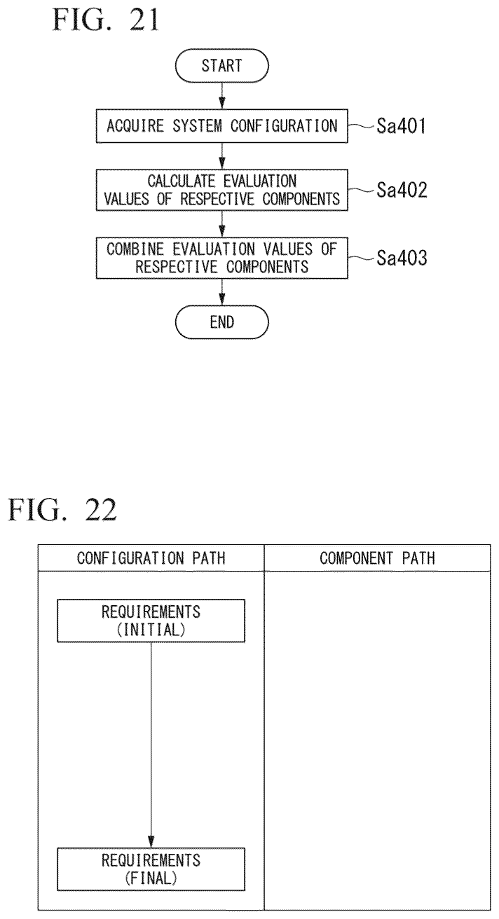

FIG. 21 is a flow chart indicating an example of a requirement evaluation process according to the present embodiment. This flow chart indicates an example of a processing procedure for calculating evaluation values for system requirements.

In the process in FIG. 21, the rule application evaluation unit C154 acquires evaluation target system requirements (Step Sa401).

Then, the rule application evaluation unit C154 uses the component evaluation model trained in step Sa25 in FIG. 17 to calculate evaluation values for the respective components included in the system being evaluated (step Sa402).

Specifically, the rule application evaluation unit C154 inputs the system requirements to be evaluated to the component evaluation model and acquires evaluation values for the respective components output by the component evaluation model.

Furthermore, the rule application evaluation unit C154 calculates an evaluation value for the system overall by combining the evaluation values of the respective components (step Sa403). The method by which the rule application evaluation unit C154 combines the evaluation values of the respective components is not limited to a specific method. For example, the rule application evaluation unit C154 may calculate any one of the maximum value, the minimum value, or the mean value of the evaluation values of the respective components as the combined value of the evaluation values for the respective components. However, there is no limitation thereto.

After step Sa403, the configuration design unit C15 ends the process in FIG. 21.

As described above, the conversion rule application unit C152 performs system design for the design target system indicated by the system requirements by repeatedly applying conversion rules to the components in the design target system until design results for the system design are obtained. The design evaluation unit C153 determines evaluation values for the system design based on the design results. The rule application evaluation unit C154 determines evaluation values regarding the conversion of each of the components in the system design based on the evaluation values for the system design. The learning unit C156 is trained to select components that are to be conversion rule application targets based on training data including the evaluation values regarding conversion of the components.

In this case, with a method for training a system design model that outputs a series of conversion rules to be applied in response to the input of system requirements, the system configuration that is the target at the time of training could be different from the system configuration that is the target at the time of system design due to the fact that systems generally have various sizes and configurations. As a result thereof, there may be cases in which the system requirements provided at the time of system design are different from the system requirements provided as training data so that the series of conversion rules to be applied cannot be appropriately determined. Thus, there may be cases in which effective training cannot be performed by the method of training the system design model by outputting a series of conversion rules to be applied in response to the input of system requirements.

Meanwhile, even if the system configurations used in a field targeted by the design device 1 are different for each system, common components or similar components can be expected to be used. Due to the design device 1 undergoing training regarding conversion in units of components, components that are the same as or similar to the components used in a system that is the target at the time of system design can be expected to also be used in the system that is the target at the time of training. On this point, by undergoing training regarding conversion in units of components, the design device 1 can perform effective training even in the case in which the system configuration that is the target at the time of system design is different from the system configuration that is the target at the time of training.

### <Comparison of Processes>

The design device 1 outputs a system configuration in step S13 in FIG. 12, and in step S25 and step S26 in FIG. 13.

When outputting a system configuration in step S26, the design device 1 performs a process indicated by the history information in FIG. 15. That is, the design device 1 performs, on the input system requirements, a configuration generation process corresponding to N conversions.

In contrast therewith, in the case in which a system configuration is output in step S13, that is, in the case in which the input system definitions include prior design information, the design device 1 performs the process indicated in FIG. 22.

FIG. 22 is an explanatory diagram indicating a comparative example of a processing history according to the present embodiment.

In this diagram, final system requirements are obtained from initial system requirements. A configuration generation process is not performed, and the number of times conversion rules are applied is zero times. Thus, the design device 1 outputs a prior configuration in response to input system requirements without performing a configuration generation process. As a result thereof, the design device 1 can increase the processing speed.

Additionally, in the case in which a system configuration is output in step S25, i.e., in the case in which a reapplied conversion series is reapplied to the input system definitions, the design device 1 performs the process indicated by FIG. 22.

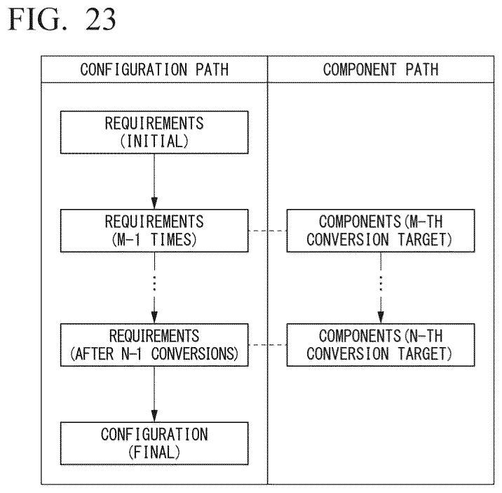

FIG. 23 is an explanatory diagram indicating a different comparative example for the processing history according to the present embodiment.

In this drawing, the component path represents components applied in a configuration generation process. That is, the component path does not describe components to which a reapplied conversion series is to be reapplied.

This diagram obtains system requirements for the case in which M−1 conversion rules have been applied, without performing a configuration generation process, by reapplying a reapplied conversion series to the initial system requirements. Thereafter, conversion rules are applied to the system requirements obtained the (M−1)-th time, thereby obtaining the final system requirements. In other words, the design device 1 performs, on the input system requirements, a configuration generation process corresponding to an (N−M+1)-th conversion. As a result thereof, the design device 1 can reduce the configuration generation processes corresponding to the M−1 conversions.

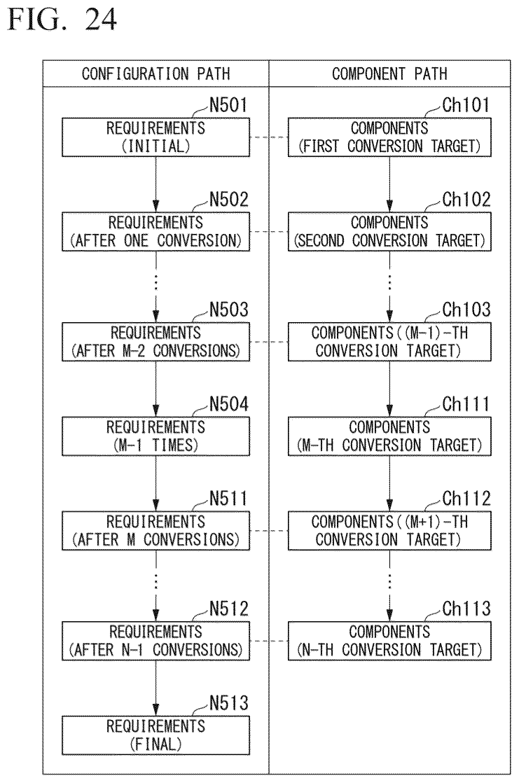

In this case, the history information becomes as shown in FIG. 24.

FIG. 24 is a diagram indicating another example of history information according to the present embodiment. This history information is for the case in which the reapplied conversion series has been reapplied. This history information is for the case in which the reapplication endpoint is the (M−1)-th system requirements N501, and the new design starting point is the M-th system requirements N502.

In the history information in this diagram, the system requirements N501 are input system requirements. The components Ch101 to Ch103 are target components of the reapplied conversion series. The system requirements N502 to N504 are system requirements converted in the order of the reapplied conversion series. The components Ch101 to Ch103 are target components of the reapplied conversion series, which are decided in advance, including conversion rules. As a result thereof, the design device 1 can reduce the processing and increase the processing speed in comparison with the case in which the configuration generation process is performed.

Meanwhile, the components Ch111 to Ch113 are components that become conversion targets during the configuration generation process. The system requirements N511 to N513 are system requirements converted in order during the configuration generation process. In this case, the system requirements N513 constitute the system configuration.

As described above, in the present embodiment, the design system performs, on a design target for which requirements are indicated, a configuration generation process for generating a system configuration (an example of configuration information) for said design target by repeatedly applying conversion rules to the configuration components that are the design targets.

The storage unit 12 stores prior design information (an example of association information) in which sets of system definitions (an example of definition information) comprising one or more requirement elements, system requirements (an example of requirement information) indicating requirements represented by groups of components (for example, nodes or edges), and system configurations indicating configurations represented by the component groups are associated in advance. When system definitions that are design targets are input, the reference determination unit C12 (an example of a determination unit) determines whether to perform a first process (step S13 in FIG. 12) for outputting a prior design information system configuration based on prior design information or to perform a second process (step S25 in FIG. 13) for outputting a system configuration generated by a configuration generation process after the reapplied conversion series has been reapplied.

The similar information acquisition unit C13, when performing the second process, selects similar system definitions (an example of similar definition information) that are system definitions similar to the design target system definitions based on prior design information, and acquires a similar system configuration (an example of similar configuration information), which is the system configuration associated with the similar system definitions.

The configuration design unit C15 generates a new system configuration with respect to input system requirements (an example of system requirements based on design target system definitions) edited by the requirement generation unit C14 by reapplying the reapplied conversion series (an example of conversion rules) that have been applied to a portion of the component group represented by the similar system requirements (an example of similar requirements), then performing a configuration generation process. The information management unit C11 stores a set including the design target system definitions and the new system configuration, as prior design information, in the storage unit 12.

Thus, the design device 1 reapplies the reapplied conversion series to the design target system requirements, and can thus reduce the configuration generation process corresponding to conversion by the reapplied conversion series. For example, the design device 1 can reduce the processes for the concretization design process, the node evaluation process, the requirement evaluation process, the training data generation process, and the training process by a number of times corresponding to the conversion by the reapplied conversion series. As a result thereof, the design device 1 can increase the processing speed.

Additionally, for example, the design device 1 can also receive, as an input, a graph structure of system requirements for an undesigned system configured from abstract elements (for example, new system requirements that do not exist in prior design information, such as edited system requirements), and generate a concrete system configuration. Furthermore, when generating a system configuration, the design device 1 reapplies a reapplied conversion series, that is, partially reuses prior design information. Thus, a system configuration can be efficiently generated even from new system requirements.

The configuration design unit C15 may generate a new system configuration not only from edited input system requirements, but also by reapplying, to newly prepared input system requirements (an example of system requirements based on design target system definitions), a reapplied conversion series applied to a portion of a component group represented by a similar system configuration, then performing a configuration generation process.

Additionally, in the present embodiment, the requirement generation unit C14 provides a user interface by which a user can edit components represented by the similar system requirements, and generates new system requirements by reflecting the edits input by the user interface to the similar requirement information. The configuration design unit C15 generates new configuration information by reapplying a reapplied conversion series to new system requirements that have been generated, then performing a configuration generation process. The information management unit C11 stores a set of the design target system definitions, the new system requirements, and the new system configuration in the storage unit 12 as prior design information.

As a result thereof, the user can use similar system requirements for which the system definitions are similar to design new system requirements. Thus, system requirements can easily be designed in comparison with the case in which system requirements are prepared from the beginning. Additionally, the user can reference past system requirements and there are cases in which new system requirements with high quality can be designed. Additionally, since the design device 1 reapplies a reapplied conversion series of a similar system configuration to the new system requirements, even when the system requirements are new, more conversion rules can be applied from among conversion rules of the reapplied conversion series. Thus, the design device 1 can further reduce the configuration generation process. As a result thereof, the design device 1 can increase the processing speed.

The similar information acquisition unit C13 selects similar system definitions based on matches between requirement elements of system definitions of a design target and requirement elements in prior definitions in prior design information.

Thus, the design device 1, for system requirements that are represented by graph elements and that are input to a configuration generation process, uses the requirement elements therein to select similar system definitions. In other words, the design device 1 uses the requirement elements to determine similarity of system requirements and to perform a configuration generation process based on similar system requirements. For example, in the case in which graph elements of system requirements are used to determine similarity, the similarity with requirement elements other than the major requirement elements may be evaluated to be low, and there are cases in which a desired system configuration cannot be obtained. Since the design device 1 uses requirement elements to evaluate similarity, the similarity of system requirements can be appropriately evaluated, and thereafter, a desired system configuration can be obtained as a result of a configuration generation process based on the similar system configuration.

The similar information acquisition unit C13 may identify, as similar system definitions, system definitions for which the value of the system type matches that of input system definitions, for which the number of values matching those of requirement elements that make up the input system definitions is equal to or greater than a predetermined threshold value, and for which a storage timing is the most recent or for which a predetermined order of priority is the highest. Thus, the similar information acquisition unit C13 may select a similar system definition based on the storage timing or the order of priority. The order of priority is based on, for example, the order of higher user evaluations of the system configuration, the order of higher evaluations of reliability, etc. of systems implemented in accordance with the design, the order of the larger number of times the system configuration has been adopted, or an order based on graph structures. An order based on graph structures is the order of fewer or more graph elements, the order of values (for example, totals) calculated based on weightings of graph elements in graph structures for weighted graph elements, the order of fewer or more nodes or edges, the order of fewer or more number of times that conversion rules have been applied, etc.

Additionally, in the present embodiment, at least some of the components are graph elements representing nodes or edges. The output control unit C16 displays an input form G11 for receiving inputs of requirement elements from a user and, with respect to system definitions comprising requirement elements input to the input form G11, a graph structure G13 including images of graph elements regarding a system configuration corresponding to said system definitions. The display unit 14 displays the input form G11 and the graph structure G13 based on screen display data or control from the output control unit C16.

As a result thereof, when a user has input requirement elements, the design device 1 can allow the user to reference a system configuration represented by graph elements as a design proposal.

The output control unit C16 may provide a user interface allowing a user to identify whether a displayed graph structure G13 was output by a process for outputting a system configuration from prior design information based on prior design information, or was generated by a process for outputting a system configuration generated by a configuration generation process after a reapplied conversion series has been reapplied.

As a result thereof, the design device 1 can allow a user to identify whether a displayed system configuration is prior design information that has been previously designed or has been newly generated by reapplying a reapplied conversion series.

The output control unit C16 may provide a user interface allowing a user to identify a first process, a second process, and a third process (step S26 in FIG. 12) for outputting a system configuration generated by performing a configuration generation process on input system requirements.

As a result thereof, the design device 1 can further allow the user to identify whether a displayed system configuration is not similar to any prior design information, or whether a reapplied conversion was not able to be reapplied. In other words, a user can identify that a design having no precedents is being performed, and can respond by checking a displayed system configuration more closely, etc.

Additionally, in the present embodiment, the prior design information includes information representing conversion steps at which conversion rules are applied during a configuration generation process, and component groups at the respective conversion steps. The configuration design unit C15 (for example, the reapplication determination unit C151) determines conversion steps for performing a configuration generation process based on a component group including system requirements based on system definitions of a design target, and component groups of respective conversion steps in a similar system configuration. In this case, the system requirements based on the system definitions of a design target are system requirements of a requirement template, edited system requirements, or system requirements to which conversion rules have been applied.

For example, the design device 1 determines a reapplication endpoint or a new design starting point by determining whether or not a portion of a conversion series of a similar system configuration can be reapplied. Due to this determination, the design device 1 can, with respect to input system requirements, reapply a reapplied conversion series up to the reapplication endpoint and can perform a configuration generation process from the new design starting point.

The “system requirements based on system definitions of a design target” may be system requirements that are not edited by a requirement generation unit C14, etc., that is, they may be system requirements in which system definitions are described by graph structures.

Additionally, in the present embodiment, the conversion steps of the similar system configuration include steps for converting first components or a first component group to second components or a second component group (see FIG. 15). The configuration design unit C15 performs a configuration generation process on fourth components (for example, components Ch11 to Ch113 in FIG. 24) or a fourth component group not included among the first components or the first component group among the third components or the third component group to which a conversion rule is applied. The configuration design unit C15 performs a conversion in which a conversion rule of a reapplied conversion series is reapplied to fifth components (for example, components Ch101 to Ch103 in FIG. 24) or a fifth component group not included among the first components or the first component group among the third components or the third component group.

Thus, the design device 1, in the case in which a component group represented by system requirements includes a target component that has been a conversion target in a conversion step for a similar system configuration, reapplies the reapplied conversion series to that component, and in the case in which a target component is not included, performs a configuration generation process on that component. As a result thereof, the design device 1 can reapply a reapplied conversion series to a portion of a component group represented by input system requirements, and can perform a configuration generation process on other portions.

The output control unit C16 may provide a user interface allowing a user to identify graph elements that are identical and graph elements that are different between a new system configuration and a similar system configuration. In this case, the new system configuration is a system configuration in which a reapplied conversion series of a similar system configuration has been reapplied to a portion of the input system requirements.

As a result thereof, the design device 1 can allow a user to identify, regarding the respective graph elements in a new system configuration, whether a reapplied conversion series has been reapplied thereto, or a configuration generation process has been performed thereon. For example, a user can know which configurations (graph elements) are new in a system configuration, and can prepare new configurations. More specifically, a user can more carefully analyze or implement procurement of components and evaluation of software or data with respect to new configurations than with respect to existing configurations (configurations in a similar system configuration).

Additionally, in the present embodiment, a trained model (for example, the search tree in FIG. 3) is stored in the storage unit 12 (an example of a storage medium). This trained model is a trained model used in the design device 1 that performs, with respect to a design target for which requirements are indicated, a configuration generation process for generating a system configuration for the design target by repeatedly applying conversion rules to the configuration components in the design target. The trained model is generated by performing machine learning based on sets of system requirements indicating requirements represented by component groups and system configurations indicating configurations represented by the component groups.

The trained model is a trained model to which a new system configuration has been added by performing a configuration generation process after having reapplied, to system requirements based on the system definitions of a design target, a reapplied conversion series applied to a portion of a component group represented by a similar system configuration associated with similar system definitions that are similar to the system definitions of the design target in prior design information in which sets of system definitions comprising one or more requirement elements, system requirements, and system configurations are associated in advance.

### Second Embodiment

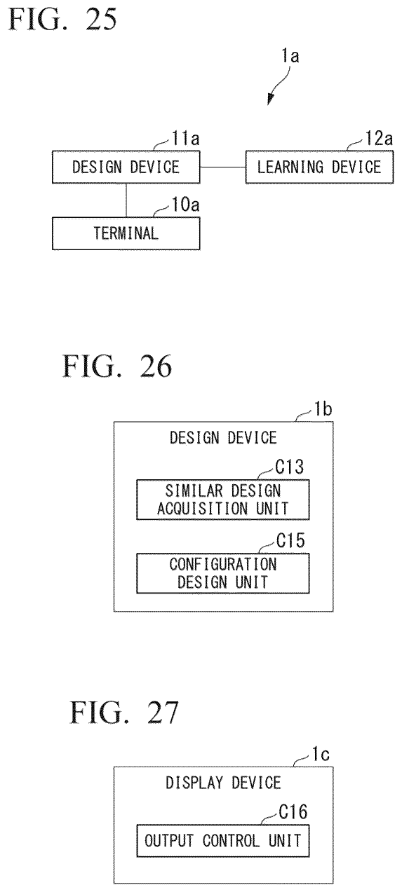

FIG. 25 is a schematic block diagram illustrating the configuration of a design system 1a according to a second embodiment. A system configured from a single design device 1, as in the first embodiment, and a system configured from multiple devices, are both referred to as a “design system”.

The design system 1a is provided with a terminal 10a, a design device 11a, and a learning device 12a. Thus, the design device 1 of the first embodiment may have some or all of the configuration thereof provided on multiple devices, and the multiple devices may be provided with configurations other than the configurations of the design device 1.

For example, the terminal 10a receives screen display information generated by the output control unit C16 in the design device 11a, and uses a browser or an application to display the screen display in FIG. 2 on a display of the terminal 10a.

The design device 11a is configured to include the communication unit 11, the storage unit 12, the operation input unit 13, and the information management unit C11, the reference determination unit C12, the similar design acquisition unit C13, the requirement generation unit C14, and the output control unit C16 in FIG. 8.

The learning device 12a is configured to include the communication unit 11, the storage unit 12, the operation input unit 13, and the configuration design unit C15 in FIG. 8.

FIG. 26 is a schematic block diagram illustrating the configuration of a design device 1b according to a modified example of the above-mentioned embodiment. The design device 1b performs, with respect to a design target for which requirements are indicated, a configuration generation process for generating a system configuration of the design target by repeatedly applying conversion rules to configuration components of the design target. The design device 1b (an example of an information processing device) is configured to include a similar information acquisition unit C13 and a configuration design unit C15.

The similar information acquisition unit C13, in the case in which system definitions of a design target have been input, acquires a similar system configuration, which is configuration information associated with similar system definitions similar to the system definitions of the design target, based on prior design information in which sets of system definitions comprising one or more requirement elements, system requirements indicating requirements represented by component groups, and system configuration information indicating configurations represented by the component groups are associated in advance.

The configuration design unit C15, with respect to system requirements based on system definitions of the design target, generates new configuration information by performing a configuration generation process after having reapplied a reapplied conversion series applied to a portion of a component group represented by a similar system configuration.

Thus, the design device 1 reapplies a reapplied conversion series to the system requirements of the design target, thereby allowing configuration conversion processes corresponding to conversion by the reapplied conversion series to be reduced. As a result thereof, the design device 1 can increase the processing speed.

FIG. 27 is a schematic block diagram illustrating the configuration of a display device 1c according to a modified example of the above-mentioned embodiment. The display device 1c displays, with respect to a design target for which requirements are indicated, a system configuration for the design target generated by repeatedly applying conversion rules to configuration components of the design target. The display device 1c (an example of an output device) is configured to include an output control unit C16.

The output control unit C16 displays an input form G11 for receiving inputs of requirement elements from a user and, with respect to system definitions comprising requirement elements input to the input form G11, a graph structure G13 including images of graph elements for a system configuration corresponding to said system definitions. The display unit 14 displays the input form G11 and the graph structure G13 based on screen display data or control from the output control unit C16.

As a result thereof, when a user has input requirement elements, the design device 1 can allow the user to reference a system configuration represented by graph elements as a design proposal.

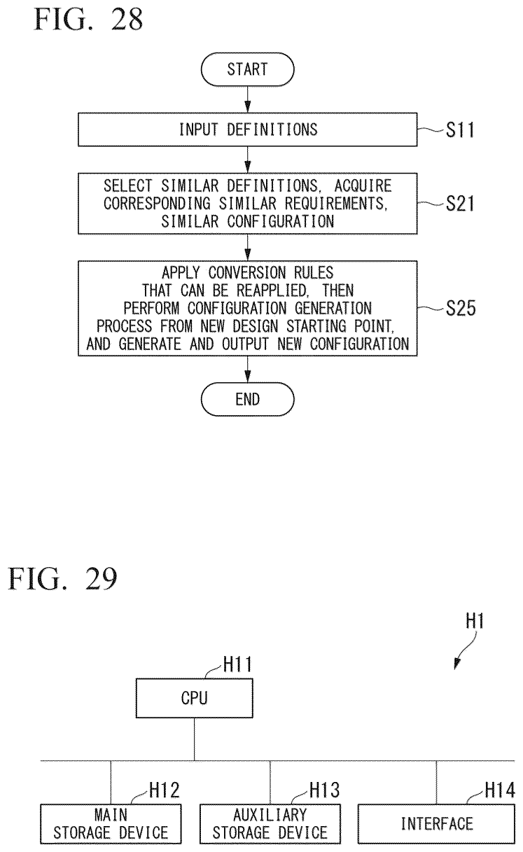

FIG. 28 is a flow chart indicating the process in the design system according to a modified example of the above-mentioned embodiment. The design system is constituted by one or a plurality of devices including a portion of the configuration of the design device 1.

System definitions (input system definitions) of the design target are input to the design device (S11). The similar design acquisition unit C13 selects, from prior design information, similar system definitions that are similar to the input system definitions. The similar design acquisition unit C13 acquires similar design information including the selected similar system definitions, that is, a similar system configuration and a similar system configuration corresponding to the similar system definitions (step S21). The configuration design unit C15 applies the conversion rules of the conversion series in the similar system configuration up to the reapplication endpoint. Thereafter, the configuration design unit C15 performs a configuration generation process from the new design starting point and as a result thereof, generates and outputs a new configuration (step S25).

FIG. 29 is a schematic block diagram illustrating the configuration of a computer according to at least one embodiment. Any one or more of the above may be implemented on a computer H1.

For example, any one or more of the design device 1, the terminal 10a, the design device 11a, the learning device 12a, the design device 1b, or the display device 1c described above may be implemented on a computer H1. In that case, the operations of the respective processing units mentioned above are stored in the auxiliary storage device H13 in the form of a program. The CPU (central processing unit) H11 reads the program from the auxiliary storage device H13 and loads the program in the main storage device H12, then executes the processes described above in accordance with said program. Additionally, the CPU H11 secures, in the main storage device H12, storage areas corresponding to the respective storage units mentioned above in accordance with the program.

When the design device 1 is implemented in the computer H1, the operations of the control unit C and other units thereof are stored in the auxiliary storage device H13 in the form of a program. The CPU H11 reads the program from the auxiliary storage device H13 and loads the program in the main storage device H12, then executes the processes described above in accordance with said program.

Additionally, the CPU H11 secures, in the main storage device H12, a storage area corresponding to the storage unit 12 in accordance with the program.

The communication by the communication unit 11 is executed by the interface H14 having a communication function and communicating in accordance with control by the CPU H11.

The display by the display unit 14 is executed by the interface H14 being provided with a display screen and displaying various images in accordance with control by the CPU H1l. The reception of user operations by the operation input unit 13 is executed by the interface H14 being provided with an input device and receiving user operations, and outputting signals indicating the received user operations to the CPU H11.

The functions of the design device 1, the design system 1a, the terminal 10a, the design device 11a, the learning device 12a, the design device 1b, or the display device 1c in the embodiments described above may be realized by a computer. In that case, a program for realizing the functions of these devices may be recorded on a computer-readable recording medium, and the functions may be realized by reading the program recorded on this recording medium into a computer system and executing the program. The “computer system” mentioned here includes an OS (operating system) and hardware such as peripheral devices. Additionally, the “computer-readable recording medium” refers to portable media such as flexible disks, magneto-optic disks, ROMs (Read-Only Memory), and CD-ROMs (compact disc read-only memory), or to storage devices, such as hard disks, internal to computer systems. Furthermore, the “computer-readable recording medium” may include media that dynamically hold the program for a short time, such as communication lines in the case in which the program is transmitted over a communication network, such as telephone lines, or a network such as the internet, and media that hold the program for a certain time, such as volatile memory inside a computer system serving as a server or as a client in such cases. Additionally, the above-mentioned program may be for realizing just some of the aforementioned functions, and may be for realizing the aforementioned functions by being combined with a program already recorded on the computer system.

Additionally, the above-mentioned program may be transmitted from a computer system that stores this program in a storage device, etc. to another computer system via a transmission medium or by transmission waves in the transmission medium. In this case, a “transmission medium” for transmitting the program refers to a medium having the function of transmitting information, like a network (communication network) such as the internet or a communication line (communication cable) such as a telephone line. Additionally, the above-mentioned program may be for realizing just some of the aforementioned functions. Furthermore, it may be a so-called difference file (difference program) that can realize the aforementioned functions by being combined with a program already recorded on a computer system.

Additionally, the respective configurations of the design device 1, the design system 1a, the terminal 10a, the design device 11a, the learning device 12a, the design device 1b, or the display device 1c may be realized by multiple devices. The multiple devices may realize the respective configurations by communicating. The multiple devices may include a user terminal.

### Appendix

(1) A design system for performing a configuration generation process for generating, with respect to a design target for which requirements are indicated, configuration information for the design target by repeatedly applying conversion rules to configuration components of the design target, the design system comprising: a storage unit that stores association information in which a set of definition information comprising one or multiple requirement elements, requirement information indicating the requirements represented by a component group, and configuration information indicating a configuration represented by a component group have been associated in advance; a determination unit that determines, based on the association information, in a case in which definition information for the design target has been input, whether to perform a first process for outputting configuration information in the association information or to perform a second process for outputting configuration information generated by the configuration generation process; a similar information acquisition unit that selects, based on the association information, in a case in which the second process is to be performed, similar definition information, which is definition information similar to definition information of the design target, and that acquires similar requirement information, which is requirement information associated with the similar definition information; a configuration design unit that generates new configuration information by applying conversion rules that were applied to a portion of a component group represented by the similar requirement information to requirement information based on the definition information of the design target, and thereafter performing the configuration generation process; and an information management unit that stores, in the storage unit, as the association information, a set including the definition information of the design target and the new configuration information.

(2) The design system according to (1), comprising:
a requirement generation unit that provides a user interface allowing a user to edit components represented by the similar requirement information, and that generates new requirement information by reflecting edits input by the user interface in the similar requirement information; wherein the configuration design unit generates the new configuration information by applying conversion rules that were applied to a portion of a component group represented by the similar requirement information to the new requirement information, and thereafter performing the configuration generation process; and the information management unit stores, in the storage unit, as the association information, a set including the definition information of the design target, the new requirement information, and the new configuration information.

(3) The design system according to (1) or (2), wherein the similar information acquisition unit selects the similar definition information based on a number of matches between requirement elements in the definition information of the design target and requirement elements in definition information of the association information.

(4) The design system according to any one of (1) to (3), wherein at least a portion of the components in the component group is a graph element representing a node or an edge, and the design system comprises an output control unit that displays an input form for receiving inputs of the requirement elements from a user, and a graph structure that, with respect to definition information comprising requirement elements input to the input form, includes an image of the graph element regarding configuration information associated with the definition information.

(5) The design system according to (4), wherein the output control unit presents a user interface allowing the user to identify whether the graph structure that is displayed is information output by the first process or information generated by the second process.

(6) The design system according to any one of (1) to (3), wherein the association information includes information representing conversion steps in which the conversion rules are applied in the configuration generation process, and component groups in the respective conversion steps; and the configuration design unit determines a conversion step for performing the configuration generation process, based on a component group included in requirement information based on the definition information of the design target, and component groups in respective conversion steps of similar configuration information, which is configuration information associated with the similar definition information.

(7) The design system according to (6), wherein the conversion step for the similar configuration information includes a step for converting first components or a first component group to second components or a second component group; and the configuration design unit performs the configuration generation process on fourth components or a fourth component group that does not include the first components or the first component group among third components or a third component group to which the conversion rules are applied.

(8) The design system according to (4), wherein the output control unit presents a user interface allowing a user to identify the graph element that is identical and the graph element that is different in the new configuration information and similar configuration information, which is configuration information associated with the similar definition information.

(9) An information processing device that is a configuration design device for performing a configuration generation process for generating, with respect to a design target for which requirements are indicated, configuration information for the design target by repeatedly applying conversion rules to configuration components of the design target, the information processing device comprising: a similar information acquisition unit that, when definition information for the design target has been input, acquires similar requirement information, which is requirement information associated with definition information similar to definition information of the design target, based on association information in which a set of definition information comprising one or multiple requirement elements, requirement information indicating the requirements represented by a component group, and configuration information indicating a configuration represented by a component group have been associated in advance; and a configuration design unit that generates new configuration information, by applying conversion rules that were applied to a portion of a component group represented by the similar requirement information to requirement information based on the definition information of the design target, and thereafter performing the configuration generation process.

(10) A storage medium having, stored therein, a trained model to be used in a configuration design device for performing a configuration generation process for generating, with respect to a design target for which requirements are indicated, configuration information for the design target by repeatedly applying conversion rules to configuration components of the design target, wherein: the trained model is generated by performing machine learning based on sets of requirement information indicating the requirements represented by component groups and configuration information indicating configurations represented by the component groups; and new configuration information is added to the trained model by applying, to requirement information based on definition information of the design target, conversion rules that were applied to a portion of a component group represented by similar requirement information associated with definition information similar to the definition information of the design target in association information in which a set of definition information comprising one or multiple requirement elements, the requirement information, and the configuration information have been associated in advance, and thereafter performing the configuration generation process.

(11) An output device for displaying, with respect to a design target for which requirements are indicated, configuration information of the design target generated by repeatedly applying conversion rules to configuration components of the design target, wherein the output device comprises an output control unit that displays, on a display, an input form for receiving inputs of requirement elements from a user, and with respect to definition information comprising requirement elements input to the input form, a graph structure including images of the graph elements regarding configuration information associated with the definition information by referencing association information in which a set of definition information comprising one or multiple requirement elements, requirement information indicating the requirements represented by a first group of graph elements representing nodes or edges, and configuration information indicating configurations represented by a second group of the graph elements have been associated in advance.

(12) A method in a design system for performing a configuration generation process for generating, with respect to a design target for which requirements are indicated, configuration information for the design target by repeatedly applying conversion rules to configuration components of the design target, wherein the method involves: storing association information in which a set of definition information comprising one or multiple requirement elements, requirement information indicating the requirements represented by a component group, and configuration information indicating a configuration represented by a component group have been associated in advance; determining, based on the association information, in a case in which definition information for the design target has been input, whether to perform a first process for outputting configuration information in the association information or to perform a second process for outputting configuration information generated by the configuration generation process; selecting, based on the association information, in a case in which the second process is to be performed, similar definition information, which is definition information similar to definition information of the design target, and acquiring similar requirement information, which is requirement information associated with the similar definition information; and generating new configuration information, by applying conversion rules that were applied to a portion of a component group represented by the similar requirement information to requirement information based on the definition information of the design target, and thereafter performing the configuration generation process.

While embodiments of the present invention have been explained in detail by referring to the drawings above, the specific configuration is not limited to these embodiments, and designs, etc. within a range not departing from the spirit of the present invention are included.

### INDUSTRIAL APPLICABILITY

The present disclosure can be used in a computer such as a personal computer, a server, or a smartphone, for example, in a design device such as a product design device or a service design device (e.g., a system design device), in an integrated circuit (e.g., a CPU (Central Processing Unit) or a communication chip) mounted therein, or in a program, etc. executed thereby.

### REFERENCE SIGNS LIST

1, 11a, 11b Design device
11 Communication unit
12 Storage unit
13 Operation input unit
14 Display unit
C Control unit
C11 Information management unit
C12 Reference determination unit
C13 Similar design acquisition unit
C14 Requirement generation unit
C15 Configuration design unit
C151 Reapplication determination unit
C152 Conversion rule application unit
C153 Design evaluation unit
C154 Rule application evaluation unit
C155 Training data generation unit
C156 Learning unit
C16 Output control unit
1a Design system
10a Terminal
12a Learning device
1c Display device

What is claimed is:

1. A design system for performing a configuration generation process for generating, with respect to a design target for which requirements are indicated, configuration information for the design target by repeatedly applying conversion rules to configuration components of the design target, the design system comprising:
at least one memory configured to store instructions and association information in which a set of definition information comprising one or multiple requirement elements, requirement information indicating the requirements represented by a component group, and configuration information indicating a configuration represented by a component group have been associated in advance; and
at least one processor configured to execute the instructions to:
determine, based on the association information, in a case in which definition information for the design target has been input, whether to perform a first process for outputting configuration information in the association information or to perform a second process for outputting configuration information generated by the configuration generation process;
select, based on the association information, in a case in which the second process is to be performed, similar definition information, which is definition information similar to definition information of the design target, and that acquires similar requirement information, which is requirement information associated with the similar definition information;
generate new configuration information by applying conversion rules that were applied to a portion of a component group represented by the similar requirement information to requirement information based on the definition information of the design target, and thereafter performing the configuration generation process; and
store, in the at least one memory, as the association information, a set including the definition information of the design target and the new configuration information.

2. The design system according to claim 1,
wherein the at least one processor is further configured to execute the instructions to provide a user interface allowing a user to edit components represented by the similar requirement information, and generate new requirement information by reflecting edits input by the user interface in the similar requirement information;
wherein the at least one processor is configured to execute the instructions to:
generate the new configuration information by applying conversion rules that were applied to a portion of a component group represented by the similar requirement information to the new requirement information, and thereafter performing the configuration generation process; and
store, in the at least one memory, as the association information, a set including the definition information of the design target, the new requirement information, and the new configuration information.

3. The design system according to claim 1, wherein the at least one processor is configured to execute the instructions to:
select the similar definition information based on a number of matches between requirement elements in the definition information of the design target and requirement elements in definition information of the association information.

4. The design system according to claim 1, wherein at least a portion of the components in the component group is a graph element representing a node or an edge, and
the at least one processor is configured to execute the instructions to display
an input form for receiving inputs of the requirement elements from a user, and
a graph structure that, with respect to definition information comprising requirement elements input to the input form, includes an image of the graph element regarding configuration information associated with the definition information.

5. The design system according to claim 4, wherein the at least one processor is configured to execute the instructions to:
present a user interface allowing the user to identify whether the graph structure that is displayed is information output by the first process or information generated by the second process.

6. The design system according to claim 1, wherein
the association information includes information representing conversion steps in which the conversion rules are applied in the configuration generation process, and component groups in the respective conversion steps; and
the at least one processor is configured to execute the instructions to determine a conversion step for performing the configuration generation process, based on a component group included in requirement information based on the definition information of the design target, and component groups in respective conversion steps of similar configuration information, which is configuration information associated with the similar definition information.

7. The design system according to claim 6, wherein
the conversion step for the similar configuration information includes a step for converting first components or a first component group to second components or a second component group; and
the at least one processor is configured to execute the instructions to perform the configuration generation process on fourth components or a fourth component group that does not include the first components or the first component group, among third components or a third component group to which the conversion rules are applied.

8. The design system according to claim 4, wherein
the at least one processor is configured to execute the instructions to present a user interface allowing a user to identify the graph element that is identical and the graph element that is different in the new configuration information and similar configuration information, which is configuration information associated with the similar definition information.

9. An information processing device that is a configuration design device for performing a configuration generation process for generating, with respect to a design target for which requirements are indicated, configuration information for the design target by repeatedly applying conversion rules to configuration components of the design target, the information processing device comprising:
at least one memory configured to store instructions; and
at least one processor configured to execute the instructions to:
acquire, when definition information for the design target has been input, similar requirement information, which is requirement information associated with definition information similar to definition information of the design target, based on association information in which a set of definition information comprising one or multiple requirement elements, requirement information indicating the requirements represented by a component group, and configuration information indicating a configuration represented by a component group have been associated in advance; and
generate new configuration information, by applying conversion rules that were applied to a portion of a component group represented by the similar requirement information to requirement information based on the definition information of the design target, and thereafter performing the configuration generation process.

10. A non-transitory storage medium having, stored therein, a trained model to be used in a configuration design device for performing a configuration generation process for generating, with respect to a design target for which requirements are indicated, configuration information for the design target by repeatedly applying conversion rules to configuration components of the design target, wherein:
the trained model is generated by performing machine learning based on sets of requirement information indicating the requirements represented by component groups and configuration information indicating configurations represented by the component groups, and
new configuration information is added to the trained model by applying, to requirement information based on definition information of the design target, conversion rules that were applied to a portion of a component group represented by similar requirement information associated with definition information similar to the definition information of the design target in association information in which a set of definition information comprising one or multiple requirement elements, the requirement information, and the configuration information have been associated in advance, and thereafter performing the configuration generation process.

11-12. (canceled)
